(19) United States
(12) Patent Application Publication
(10) Pub. No.: US 2026/0040674 A1
(43) Pub. Date: Feb. 5, 2026

(54) MONOLITHIC STACKED COMPLEMENTARY TRANSISTOR STRUCTURES WITH DUAL WORK FUNCTION METAL GATES

(71) Applicant: International Business Machines Corporation, Armonk, NY (US)

(72) Inventors: Takashi Ando, Eastchester, NY (US); Shay Reboh, Guilderland, NY (US); Shahrukh Khan, Sandy Hook, CT (US); Jay William Strane, Wappingers Falls, NY (US)

(21) Appl. No.: 18/791,644

(22) Filed: Aug. 1, 2024

(51) Int. Cl. H01L 27/092; H01L 21/28; H01L 21/822; H01L 21/8238; H01L 29/06; H01L 29/423; H01L 29/49; H01L 29/66; H01L 29/775; H01L 29/786

(52) U.S. Cl. CPC H10D 84/856; H01L 21/28088; H10D 30/014; H10D 30/43; H10D 30/6735; H10D 30/6739; H10D 30/6757; H10D 62/121; H10D 64/017; H10D 84/0177; H10D 84/038; H10D 88/01

(57) ABSTRACT

A device comprises a stacked transistor structure, and a shared gate structure. The stacked transistor structure comprises a first transistor of a first type, and a second transistor of a second type which is opposite the first type, and disposed over the first transistor. The shared gate structure comprises a first metal gate structure of the first transistor, and a second metal gate structure of the second transistor. The second metal gate structure is embedded in the first metal gate structure.

### BACKGROUND

This disclosure relates generally to monolithic three-dimensional (3D) integration techniques and, in particular, techniques for fabricating monolithic 3D semiconductor integrated circuit devices comprising stacked complementary metal-oxide semiconductor (CMOS) transistor structures. Continued innovations in semiconductor process technologies are enabling higher integration densities and device scaling. In particular, state-of-the-art 3D integration technologies are poised to become critical technology boosters for providing extremely dense integrated circuits. A 3D monolithic design comprises stacked layers of field-effect transistor (FET) devices to reduce a device footprint. For example, a FET-over-FET integration scheme is one form of a 3D monolithic integration scheme in which p-type FET (PFET) and n-type FET (NFET) devices are formed in different device layers on a single substrate. While stacked CMOS structures allow for increased transistor density by stacking PFET devices and NFET devices on top of each other, the ability to form dual work function metal gate layers to optimize device performance of the stacked P-type and N-type FET devices is not trivial.

### SUMMARY

Exemplary embodiments of the disclosure include semiconductor integrated circuit devices comprising stacked transistor structures (e.g., stacked complementary transistor structures) with dual work function metal gates, and methods for fabricating such semiconductor integrated circuit devices.

For example, an exemplary embodiment includes a device which comprises a stacked transistor structure, and a shared gate structure. The stacked transistor structure comprises a first transistor of a first type, and a second transistor of a second type which is opposite the first type, and disposed over the first transistor. The shared gate structure comprises a first metal gate structure of the first transistor, and a second metal gate structure of the second transistor. The second metal gate structure is embedded in the first metal gate structure.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a first dielectric isolation layer, a first metal gate structure of the first transistor, and a second metal gate structure of the second transistor which are isolated at least in part by the first dielectric isolation layer. The second metal gate structure is embedded in the first dielectric isolation layer. The first metal gate structure is disposed below the first dielectric isolation layer.

Another exemplary embodiment includes a device which comprises a substrate, and a first stacked transistor structure and a second stacked transistor structure disposed on the substrate. The first stacked transistor structure comprises a first transistor of a first type, and a second transistor of a second type which is opposite the first type, and disposed over the first transistor; and a shared metal gate structure. The shared metal gate structure comprises a first metal gate structure of the first transistor, and a second metal gate structure of the second transistor. The second metal gate structure is embedded in the first metal gate structure. The second stacked transistor structure comprises a third transistor of a first type, and a fourth transistor of a second type which is opposite the first type, and disposed over the third transistor, and a split gate structure. The split gate structure comprises a first dielectric isolation layer, a first metal gate structure of the third transistor, and a second metal gate structure of the fourth transistor which are isolated at least in part by the first dielectric isolation layer. The second metal gate structure of the fourth transistor is embedded in the first dielectric isolation layer. The first metal gate structure of the third transistor is disposed below the first dielectric isolation layer.

Another exemplary embodiment includes a method for fabricating a semiconductor integrated circuit device. The method comprises forming a stacked transistor structure which comprises a first transistor of a first type, a second transistor of a second type, which is opposite the first type and disposed over the first transistor, and forming a shared gate structure. The shared gate structure comprises a first metal gate structure of the first transistor, and a second metal gate structure of the second transistor. The second metal gate structure is embedded in the first metal gate structure.

Another exemplary embodiment includes a method for fabricating a semiconductor integrated circuit device. The method comprises forming a stacked transistor structure which comprises a first transistor of a first type, and a second transistor of a second type which is opposite the first type, and disposed over the first transistor, and forming a split gate structure. The split gate structure comprises a first dielectric isolation layer, a first metal gate structure of the first transistor, and a second metal gate structure of the second transistor which are isolated at least in part by the first dielectric isolation layer. The second metal gate structure is embedded in the first dielectric isolation layer. The first metal gate structure is disposed below the first dielectric isolation layer.

Other embodiments will be described in the following detailed description of embodiments, which is to be read in conjunction with the accompanying figures.

### BRIEF DESCRIPTION OF THE DRAWINGS

FIGS. 1A, 1B, and 1C are schematic views of a semiconductor integrated circuit device comprising a stacked complementary transistor structure, according to an exemplary embodiment of the disclosure.

FIGS. 2A-2K schematically illustrate a method for fabricating a semiconductor integrated circuit device comprising a stacked complementary transistor structure, according to an exemplary embodiment of the disclosure, wherein:

FIG. 2A is a schematic cross-sectional side view of an intermediate structure of the device which comprises a patterned nanosheet stack structure of a stacked complementary transistor structure with a dummy gate to be replaced with a metal gate with dual work function metal layers;

FIG. 2B is a schematic cross-sectional side view of an intermediate structure of the device which is obtained after removing the dummy gate to form an open gate region which exposes the patterned nanosheet stack structure;

FIG. 2C is a schematic cross-sectional side view of an intermediate structure of the device which is obtained after selectively etching sacrificial layers of the patterned nanosheet stack structure to release nanosheet channel layers of first and second transistors;

FIG. 2D is a schematic cross-sectional side view of an intermediate structure of the device which is obtained after forming high-k dielectric layers on exposed surfaces of the nanosheet channel layers of the first and second transistors;

FIG. 2E is a schematic cross-sectional side view of an intermediate structure of the device which is obtained after depositing one or more layers of work function metal to form a first work function metal layer which initially encapsulates the nanosheet channel layers and a middle dielectric isolation layer;

FIG. 2F is a schematic cross-sectional side view of an intermediate structure of the device which is obtained after depositing a layer of sacrificial material to fill the open gate region;

FIG. 2G is a schematic cross-sectional side view of an intermediate structure of the device which is obtained after forming a trench opening in the layer of sacrificial material to expose a portion of the first work function metal layer which encapsulates the nanosheet channel layers of the second transistor;

FIG. 2H is a schematic cross-sectional side view of an intermediate structure of the device which is obtained after removing the portion of the first work function metal layer which is exposed by the trench opening in the layer of sacrificial material;

FIG. 2I is a schematic cross-sectional side view of an intermediate structure of the device which is obtained after conformally depositing one or more layers of work function metal to form a second layer work function metal layer which encapsulates the nanosheet channel layers of the second transistor;

FIG. 2J is a schematic cross-sectional side view of an intermediate structure of the device which is obtained after filling the open trench in the layer of sacrificial material with a low-resistance metallic material to form a second metal gate electrode in contact with the second work function metal layer of the second transistor; and

FIG. 2K is a schematic cross-sectional side view of an intermediate structure of the device which is obtained after removing a remaining portion of the layer of sacrificial material to form an open gate region and thereby expose the first work function metal layer of the first transistor 110.

FIG. 3 is a schematic cross-sectional side view of a semiconductor integrated circuit device comprising a stacked complementary transistor structure, according to another exemplary embodiment of the disclosure.

FIGS. 4A-4K schematically illustrate a method for fabricating a semiconductor integrated circuit device comprising a stacked complementary transistor structure, according to another exemplary embodiment of the disclosure, wherein:

FIG. 4A is a schematic cross-sectional side view of an intermediate structure of a semiconductor integrated circuit device which, starting with the intermediate structure shown in FIG. 2G, is obtained after removing the portion of the first work function metal layer which is exposed by the trench opening in the layer of sacrificial material;

FIG. 4B is a schematic cross-sectional side view of an intermediate structure of the device which is obtained after conformally depositing one or more layers of work function metal to form a second layer work function metal layer which encapsulates the nanosheet channel layers of the second transistor;

FIG. 4C is a schematic cross-sectional side view of an intermediate structure of the device which is obtained after filling the open trench in the layer of sacrificial material with a first layer of dielectric material;

FIG. 4D is a schematic cross-sectional side view of an intermediate structure of the device which is obtained after removing a remaining portion of the layer of sacrificial material to form an open gate region and thereby expose the first work function metal layer of the first transistor and a thin residual work function metal layer on the surfaces of the first layer of dielectric material;

FIG. 4E is a schematic cross-sectional side view of an intermediate structure of the device which is obtained after removing the thin residual work function metal layer on the surfaces of the first layer of dielectric material;

FIG. 4F is a schematic cross-sectional side view of an intermediate structure of the device which is obtained after filling the open gate region with a layer of low-resistance metallic material;

FIG. 4G is a schematic cross-sectional side view of an intermediate structure of the device which is obtained after recessing the layer of low-resistance metallic material down to a level below a middle dielectric isolation layer to form the first metal gate electrode;

FIG. 4H is a schematic cross-sectional side view of an intermediate structure of the device which is obtained after filling a remaining portion of the open region above the first metal gate electrode with dielectric material to form a second insulating layer;

FIG. 4I is a schematic cross-sectional side view of an intermediate structure of the device which is obtained after recessing the first layer of dielectric material down to a level of the middle dielectric isolation layer to form an open cavity which exposes the second work function metal layer and form an insulating layer which isolates the second work function metal layer from the first work function metal layer;

FIG. 4J is a schematic cross-sectional side view of an intermediate structure of the device which is obtained after filling the open cavity with a layer of low-resistance metallic material to form a second metal gate electrode which is disposed around and in contact with the second work function metal layer of the second transistor; and

FIG. 4K is a schematic cross-sectional side view of an intermediate structure of the device which is obtained after forming a deep via gate contact in the second insulating layer to provide a gate contact to the underlying first metal gate electrode of the first transistor, and after forming additional middle-of-the-line gate contacts.

### DETAILED DESCRIPTION

Exemplary embodiments will now be described in further detail with regard semiconductor integrated circuit devices comprising stacked CMOS device structures (alternatively, stacked complementary transistor structures) with dual work function metal gates, and methods for fabricating such semiconductor integrated circuit devices. For illustrative purposes, exemplary embodiments of the disclosure will be discussed in the context of stacked complementary transistor structures comprising nanosheet MOSFET devices. It is to be understood, however, that the exemplary embodiments discussed herein are readily applicable to various types of gate-all-around (GAA) FET devices such as nanowire MOSFETs, and other types of GAA MOSFET devices having gate structures that are formed around all sides of active channel layers.

For example, an exemplary embodiment includes a device which comprises a stacked transistor structure, and a shared gate structure. The stacked transistor structure comprises a first transistor of a first type, and a second transistor of a second type which is opposite the first type, and disposed over the first transistor. The shared gate structure comprises a first metal gate structure of the first transistor, and a second metal gate structure of the second transistor. The second metal gate structure is embedded in the first metal gate structure.

Advantageously, the exemplary device architecture enables a stacked transistor structure with a shared gate structure that is realized without the need to perform a partial metal recesses process to provide a stacked transistor structure with dual work function metals for the first and second transistors.

In another exemplary embodiment, which may be combined with one or more of the embodiments of the preceding paragraphs, the first metal gate structure comprises a first work function metal layer encapsulating at least one channel layer of the first transistor, and the second metal gate structure comprises a second work function metal layer encapsulating at least one channel layer of the second transistor. A first portion of the first work function metal layer is disposed in contact with a second portion of the second work function metal layer.

In another exemplary embodiment, which may be combined with one or more of the embodiments of the preceding paragraphs, the device further comprises a dielectric isolation layer disposed between the at least one channel layer of the first transistor and the at least one channel layer of the second transistor. A first portion of the dielectric isolation layer is covered by the first portion of the first work function metal layer, and a second portion of the dielectric isolation layer is covered by the second portion of the second work function metal layer.

In another exemplary embodiment, which may be combined with one or more of the embodiments of the preceding paragraphs, the first metal gate structure comprises a first work function metal layer encapsulating at least one channel layer of the first transistor, and a first gate electrode in contact with the first work function metal layer, and the second metal gate structure comprises a second work function metal layer encapsulating at least one channel layer of the second transistor, and a second gate electrode in contact with the second work function metal layer. The first gate electrode and the second gate electrode are electrically coupled by a portion of the second work function metal layer disposed between and in contact with the first gate electrode and the second gate electrode.

In another exemplary embodiment, which may be combined with one or more of the embodiments of the preceding paragraphs, the first transistor and the second transistor each comprise one or more channel layers, where the one or more channel layers are encapsulated by respective dielectric layers. The dielectric layers are nominally identical in composition and thickness.

In another exemplary embodiment, which may be combined with one or more of the embodiments of the preceding paragraphs, the one or more channel layers comprise respective interfacial layers formed on surfaces thereof, where the interfacial layers are nominally identical in composition and thickness.

In another exemplary embodiment, which may be combined with one or more of the embodiments of the preceding paragraphs, the first transistor and the second transistor each comprise a gate-all-around nanosheet field-effect transistor. The first transistor is a P-type transistor and the second transistor is an N-type transistor, or the first transistor is an N-type transistor and the second transistor is a P-type transistor.

Another exemplary embodiment includes a device which comprises a stacked transistor structure, and a split gate structure. The stacked transistor structure comprises a first transistor of a first type, and a second transistor of a second type which is opposite the first type, and disposed over the first transistor. The split gate structure comprises a first dielectric isolation layer, a first metal gate structure of the first transistor, and a second metal gate structure of the second transistor, which are isolated at least in part by the first dielectric isolation layer. The second metal gate structure is embedded in the first dielectric isolation layer. The first metal gate structure is disposed below the first dielectric isolation layer.

Advantageously, the exemplary device architecture enables a stacked transistor structure with a non-shared gate structure that is realized without the need to perform a partial metal recesses process to provide a stacked transistor structure with dual work function metals for the first and second transistors.

In another exemplary embodiment, which may be combined with one or more of the embodiments of the preceding paragraphs, the first metal gate structure comprises a first work function metal layer encapsulating at least one channel layer of the first transistor, and the second metal gate structure comprises a second work function metal layer encapsulating at least one channel layer of the second transistor. The split gate structure further comprises a second dielectric isolation layer which electrically isolates the first work function metal layer and the second work function metal layer from each other.

In another exemplary embodiment, which may be combined with one or more of the embodiments of the preceding paragraphs, the device further comprises a third dielectric isolation layer disposed between the at least one channel layer of the first transistor and the at least one channel layer of the second transistor. The third dielectric isolation layer is encapsulated by a portion of the second work function metal layer, and the second dielectric isolation layer encapsulates the portion of the second work function metal layer that encapsulates the third dielectric isolation layer.

In another exemplary embodiment, which may be combined with one or more of the embodiments of the preceding paragraphs, the device further comprises a via contact disposed in the first dielectric isolation layer and in contact with the first metal gate structure disposed below the first dielectric isolation layer.

In another exemplary embodiment, which may be combined with one or more of the embodiments of the preceding paragraphs, the first transistor and the second transistor each comprise one or more channel layers, where the one or more channel layers are encapsulated by respective dielectric layers, and where the dielectric layers are nominally identical in composition and thickness.

In another exemplary embodiment, which may be combined with one or more of the embodiments of the preceding paragraphs, the one or more channel layers comprise respective interfacial layers formed on surfaces thereof, where the interfacial layers are nominally identical in composition and thickness.

In another exemplary embodiment, which may be combined with one or more of the embodiments of the preceding paragraphs, the first transistor and the second transistor each comprise a gate-all-around nanosheet field-effect transistor. The first transistor is a P-type transistor and the second transistor is an N-type transistor, or the first transistor is an N-type transistor and the second transistor is a P-type transistor.

Another exemplary embodiment includes a device which comprises a substrate, and a first stacked transistor structure and a second stacked transistor structure disposed on the substrate. The first stacked transistor structure comprises a first transistor of a first type, and a second transistor of a second type which is opposite the first type, and disposed over the first transistor; and a shared metal gate structure. The shared metal gate structure comprises a first metal gate structure of the first transistor, and a second metal gate structure of the second transistor. The second metal gate structure is embedded in the first metal gate structure. The second stacked transistor structure comprises a third transistor of a first type, and a fourth transistor of a second type which is opposite the first type, and disposed over the third transistor, and a split gate structure. The split gate structure comprises a first dielectric isolation layer, a first metal gate structure of the third transistor, and a second metal gate structure of the fourth transistor which are isolated at least in part by the first dielectric isolation layer. The second metal gate structure of the fourth transistor is embedded in the first dielectric isolation layer. The first metal gate structure of the third transistor is disposed below the first dielectric isolation layer.

Another exemplary embodiment includes a method for fabricating a semiconductor integrated circuit device. The method comprises forming a stacked transistor structure which comprises a first transistor of a first type, a second transistor of a second type, which is opposite the first type and disposed over the first transistor, and forming a shared gate structure. The shared gate structure comprises a first metal gate structure of the first transistor, and a second metal gate structure of the second transistor. The second metal gate structure is embedded in the first metal gate structure.

In another exemplary embodiment, which may be combined with one or more of the embodiments of the preceding paragraphs, the first metal gate structure comprises a first work function metal layer which encapsulates first channel layers of the first transistor, and a first gate electrode in contact with the first work function metal layer. The second metal gate structure comprises a second work function metal layer which encapsulates second channel layers of the second transistor, and a second gate electrode in contact with the second work function metal layer.

In another exemplary embodiment, which may be combined with one or more of the embodiments of the preceding paragraphs, forming the stacked transistor structure comprises forming an initial stacked transistor structure in which the first channel layers and the second channel layers are encapsulated by the first work function metal layer. In addition, forming the shared gate structure comprises: forming a sacrificial material layer over the initial stacked transistor structure; forming a trench opening in the sacrificial material layer to expose a portion of the first work function metal layer encapsulating the second channel layers of the second transistor; removing the exposed portion of the first work function metal layer; depositing a layer of work function metal to form the second work function metal layer which encapsulates the second channel layers of the second transistor and to form a liner layer of work function metal on sidewalls of the trench opening; filling the trench with metallic material to form the second gate electrode in contact with the liner layer of work function metal; removing a remaining portion of the sacrificial material layer to form an open region which exposes a remaining portion of the first work function metal layer encapsulating the first channel layers of the first transistor; and filling the open region with metallic material to form the first gate electrode in contact with the remaining portion of the first work function metal layer and the liner layer of work function metal.

In another exemplary embodiment, which may be combined with one or more of the embodiments of the preceding paragraphs, forming the trench opening in the sacrificial material layer comprises etching the trench opening down to a level of a dielectric isolation layer of the stacked transistor structure which is disposed between the first channel layers and the second channel layers.

In another exemplary embodiment, which may be combined with one or more of the embodiments of the preceding paragraphs, forming the initial stacked transistor structure comprises: forming an interfacial layer and dielectric layer on each of the first channel layers and the second channel layers; and forming the first work function metal layer to encapsulate the first channel layers and the second channel layers with the interfacial layers and dielectric layers. The interfacial layers are nominally identical in composition and thickness, and the dielectric layers are nominally identical in composition and thickness.

Another exemplary embodiment includes a method for fabricating a semiconductor integrated circuit device. The method comprises forming a stacked transistor structure which comprises a first transistor of a first type, and a second transistor of a second type which is opposite the first type, and disposed over the first transistor, and forming a split gate structure. The split gate structure comprises a first dielectric isolation layer, a first metal gate structure of the first transistor, and a second metal gate structure of the second transistor which are isolated at least in part by the first dielectric isolation layer. The second metal gate structure is embedded in the first dielectric isolation layer. The first metal gate structure is disposed below the first dielectric isolation layer.

In another exemplary embodiment, which may be combined with one or more of the embodiments of the preceding paragraphs, the first metal gate structure comprises a first work function metal layer which encapsulates first channel layers of the first transistor, and a first gate electrode in contact with the first work function metal layer. The second metal gate structure comprises a second work function metal layer which encapsulates second channel layers of the second transistor, and a second gate electrode in contact with the second work function metal layer.

In another exemplary embodiment, which may be combined with one or more of the embodiments of the preceding paragraphs, forming the stacked transistor structure comprises forming an initial stacked transistor structure in which the first channel layers and the second channel layers are encapsulated by the first work function metal layer. In addition, forming the split gate structure comprises: forming a sacrificial material layer over the initial stacked transistor structure; forming a first trench opening in the sacrificial material layer to expose a portion of the first work function metal layer encapsulating the second channel layers of the second transistor; removing the exposed portion of the first work function metal layer; depositing a work function metal to form the second work function metal layer which encapsulates the second channel layers of the second transistor and to form a liner layer of work function metal on sidewalls of the first trench opening; filling the first trench opening with a first layer of dielectric material; removing a remaining portion of the sacrificial material layer and the liner layer of work function metal to form an open region which exposes a remaining portion of the first work function metal layer encapsulating the first channel layers of the first transistor; forming the first gate electrode in a bottom portion of the open region in contact with the remaining portion of the first work function metal layer; filling a remaining portion of the open region with a second layer of dielectric material; removing the first layer of dielectric material selective to the second layer of dielectric material to form a second trench opening in the second layer of dielectric material to exposes a portion of the second work function metal layer; and forming the second gate electrode in the second trench opening in contact with the exposed portion of the second work function metal layer.

In another exemplary embodiment, which may be combined with one or more of the embodiments of the preceding paragraphs, forming the first trench opening in the sacrificial material layer comprises etching the first trench opening in the sacrificial material layer down to a level below a middle dielectric isolation layer of the stacked transistor structure which is disposed between the first channel layers and the second channel layers. In addition, filling the first trench opening with a first layer of dielectric material comprises encapsulating the middle dielectric isolation layer within the first layer of dielectric material.

In another exemplary embodiment, which may be combined with one or more of the embodiments of the preceding paragraphs, forming the initial stacked transistor structure comprises: forming an interfacial layer and dielectric layer on each of the first channel layers and the second channel layers; and forming the first work function metal layer to encapsulate the first channel layers and the second channel layers with the interfacial layers and dielectric layers. The interfacial layers are nominally identical in composition and thickness, the dielectric layers are nominally identical in composition and thickness.

It is to be understood that the various layers, structures, and regions shown in the accompanying drawings are schematic illustrations that are not drawn to scale. In addition, for case of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the same or similar reference numbers are used throughout the drawings to denote the same or similar features, elements, or structures, and thus, a detailed explanation of the same or similar features, elements, or structures will not be repeated for each of the drawings. Further, the terms “about” or “substantially” as used herein with regard to thicknesses, widths, percentages, ranges, etc., are meant to denote being close or approximate to, but not exactly. For example, the term “about” or “substantially” as used herein implies that a small margin of error is present, such as 1% or less than the stated amount. The term “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

To provide spatial context to the different structural orientations of the semiconductor structures shown throughout the drawings, XYZ Cartesian coordinates are shown in each of the drawings. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

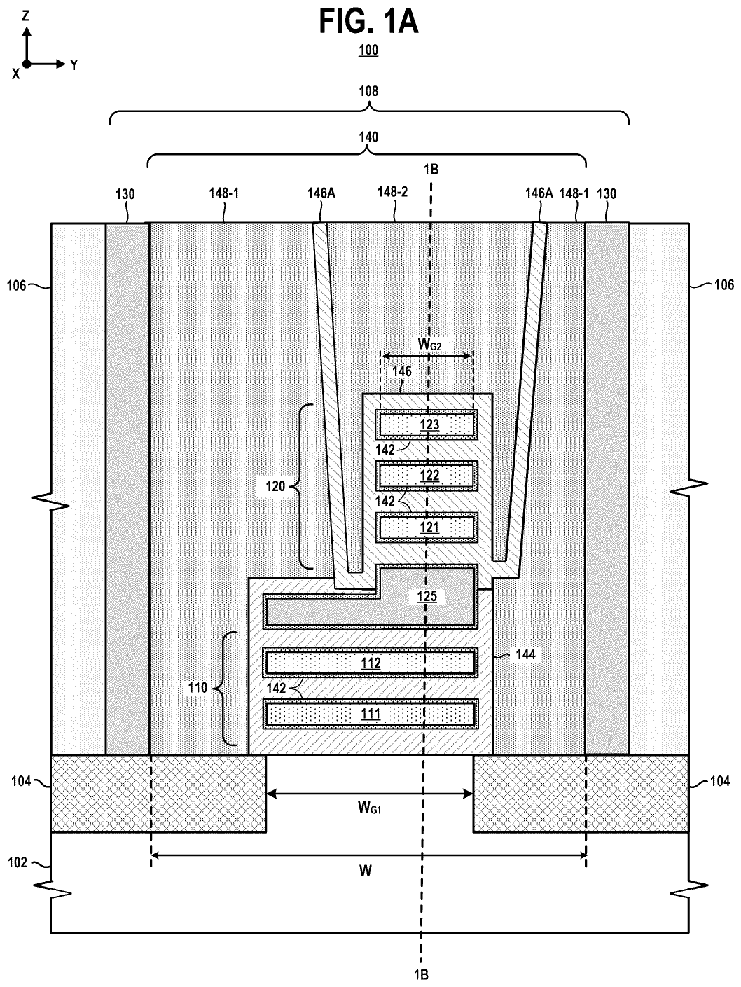

FIGS. 1A, 1B, and 1C are schematic views of a semiconductor integrated circuit device 100 (or device 100) comprising a stacked complementary transistor structure, according to an exemplary embodiment of the disclosure. In particular, FIG. 1A is a schematic cross-sectional side view of the device 100 in a Y-Z plane, while FIG. 1B is a schematic cross-sectional side view of the device 100 in an X-Z plane. FIG. IC is a schematic top plan view of the device 100 (X-Y plane). It is to be further noted that FIG. 1A is a schematic cross-sectional side view of the device 100 along line 1A-1A in FIG. 1C, and that FIG. 1B is a schematic cross-sectional side view of the device 100 along line 1B-1B in FIG. IC, and along line 1B-1B in FIG. 1A.

As collectively shown in FIGS. 1A, 1B, and IC, the device 100 comprises a substrate 102, a shallow trench isolation (STI) layer 104, a dielectric layer 106 (or pre-metallization dielectric layer 106), and a stacked complementary transistor structure 108 (e.g., stacked complementary FET structure). The stacked complementary transistor structure 108 comprises a first transistor 110, and a second transistor 120 disposed over the first transistor 110. The first transistor 110 and the second transistor 120 comprise complementary gate-all-around metal-oxide-semiconductor FET (MOSFET) devices (e.g., nanosheet FET devices). In some embodiments, the first transistor 110 comprises an N-type MOSFET, and the second transistor 120 comprises a P-type MOSFET. In other embodiments, the first transistor 110 comprises a P-type MOSFET, and the second transistor 120 comprises an N-type MOSFET.

The first transistor 110 comprises a plurality of channel layers 111 and 112 (e.g., nanosheet channel layers), a first source/drain element 118-1, and a second source/drain element 118-2. The second transistor 120 comprises a plurality of channel layers 121, 122, and 123, (e.g., nanosheet channel layers), a first source/drain element 128-1, and a second source/drain element 128-2. The channel layers of the first and second transistors 110 and 120 are separated by a dielectric isolation layer 125 (or middle dielectric isolation (MDI) layer 125) which can be formed of any suitable insulator or dielectric material, such as silicon nitride (SiN), silicon boron carbide nitride (SiBCN), silicon oxycarbonitride (SiOCN), etc.

As schematically shown in FIG. 1B, the first source/drain element 118-1 and the second source/drain element 118-2 are coupled to opposite ends of the channel layers 111 and 112 of the first transistor 110. In addition, the first source/drain element 128-1 and the second source/drain element 128-2 are coupled to opposite ends of the channel layers 121, 122, and 123 of the second transistor 120. It is to be understood that the term “source/drain element” of a given transistor as used herein means that a given source/drain element can be either a source element or a drain element of the given transistor, depending on the application or circuit configuration.

The stacked complementary transistor structure 108 further comprises a gate structure which comprises gate sidewall spacers 130 and 132, and a metal gate 140. In some embodiments, the metal gate 140 comprises a high-k metal gate (HKMG) structure comprising high-k dielectric layers 142 that are formed on the channel layers 111, 112, 121, 122, and 123 of the first and second transistors 110 and 120, a first work function metal layer 144 that encapsulates the channel layers 111 and 112 of the first transistor 110, and a second work function metal layer 146 which encapsulates the channel layers 121, 122, and 123 of the second transistor 120. The metal gate 140 further comprises a first metal gate electrode 148-1 and a second metal gate electrode 148-2, which are separated by a thin residual layer 146A of the second work function metal layer 146. The thin residual layer 146A of the second work function metal layer 146 is formed as a result of an exemplary fabrication process, as discussed in further detail below.

The gate sidewall spacers 130 and 132 define a common gate region of the first transistor 110 and the second transistor 120, which surrounds/contains the metal gate 140. As schematically shown in FIG. 1C, the gate sidewall spacer 130 serves to electrically insulate the metal gate 140 from surrounding elements (e.g., dielectric layer 106, and source/drain contacts (not shown). Moreover, as schematically shown in FIG. 1B, the gate sidewall spacers 132 comprise embedded gate sidewall spacers (or internal spacers) which are formed between end portions of the channel layers 111, 112, 121, 122, and 123. The gate sidewall spacers 132 serve to (i) insulate the first work function metal layer 144 from the first and second source/drain elements 118-1 and 118-2 of the first transistor 110, and (ii) insulate the second work function metal layer 146 from the first and second source/drain elements 128-1 and 128-2 of the second transistor 120.

As shown in FIG. 1B, the metal gate 140 encapsulates portions of the channel layers 111, 112, 121, 122, and 123, which define a gate length (L_{G}) of the first and second transistors 110 and 120, although the channel layers 111, 112, 121, 122, and 123 are physically longer (length L) than the gate length L_{G}. Moreover, as shown in FIG. 1A, the first transistor 110 comprises a first gate width W_{G1}, and the second transistor 120 comprises a second gate width W_{G2}. In some embodiments, the first gate width W_{G1} of the first transistor 110 is greater than the second gate width W_{G2} of the second transistor 120. It is to be noted that FIGS. 1A-1C illustrate a non-limiting, exemplary embodiment of a stacked complementary transistor structure in which the first transistor 110 (e.g., N-type MOSFET) and the second transistor (e.g., P-type MOSFET) have different structural configurations (e.g., different number of channel layers, different gate widths, etc.) that are designed to achieve certain properties for certain applications. However, in other embodiments, the first and second transistors 110 and 120 can have the same number of channel layers, the same gate widths, and the same gate lengths. In other embodiments, the first and second transistors 110 and 120 can have different numbers of channel layers, and have the same gate widths and same gate lengths. In this regard, it is to be noted that the exemplary fabrication methods as discussed herein can be utilized to fabricate stacked complementary transistor structures regardless of the different structural configurations (e.g., different number of channel layers, different gate widths, etc.) of the first and second transistors 110 and 120.

As is known in the art, the electrical properties of the first and second transistors 110 and 120, such as the threshold voltages (Vt) of the transistors, is based at least in part on the spacing between the nanosheet channel layers and the types of work function metals disposed in the spaces above and below the nanosheet channel layers of the transistors. In this regard, work function engineering through the implementation of dual work function metal layers for the first and second transistors 110 and 120 ensures the desired electrical properties of stacked complementary transistor structures. Conventional fabrication methods for forming dual work function metals typically involve forming a first layer of work function metal to encapsulate the channel layers of the stacked transistors, followed by a metal recess process to remove the first layer of work function metal from the upper transistor, and then forming a second layer of work function metal to encapsulate the channel layers of the upper transistor. However, such conventional methods are problematic in that it can be difficult to control the metal recess process to ensure that a sufficient amount of the first layer of work function metal is removed to thereby form the second layer of work function metal for the upper transistor, without removing too much of the first layer of work function metal, which could lead to degraded performance of bottom transistor. In this regard, exemplary fabrication techniques are provided that allow the dual work function metal layers to be precisely fabricated for the upper and lower transistor devices from the front side in monolithic integration using lithographic patterning methods, while eliminating the need to perform partial work function metal recess steps which, as noted above, are problematic.

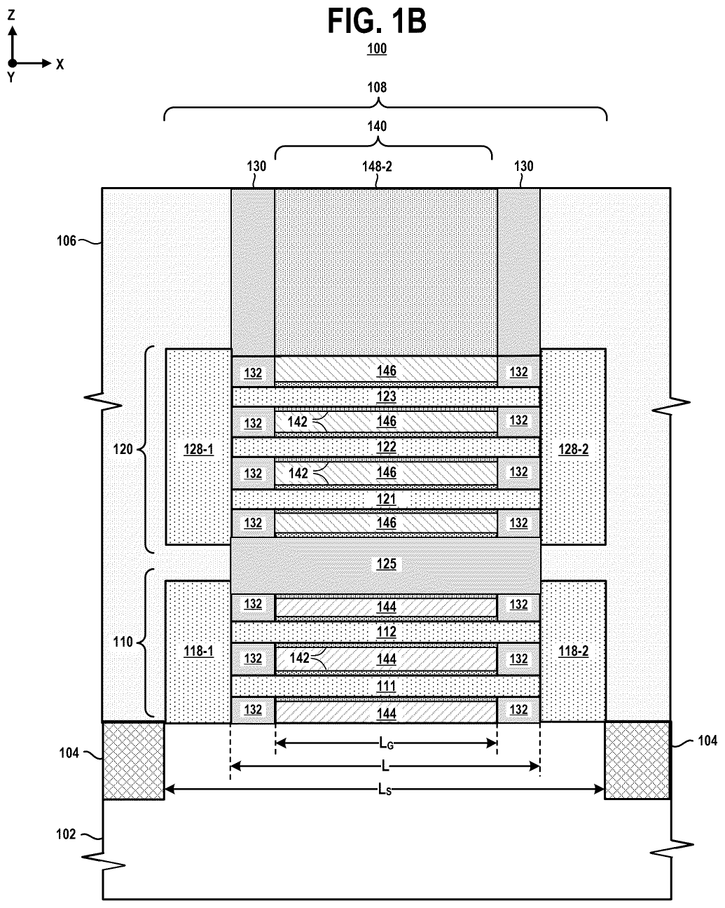

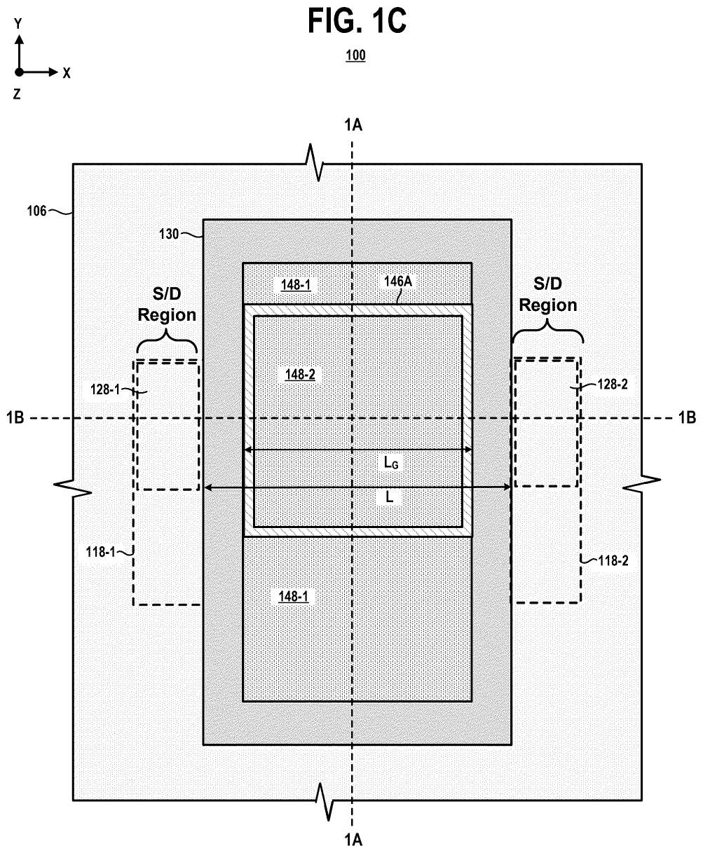

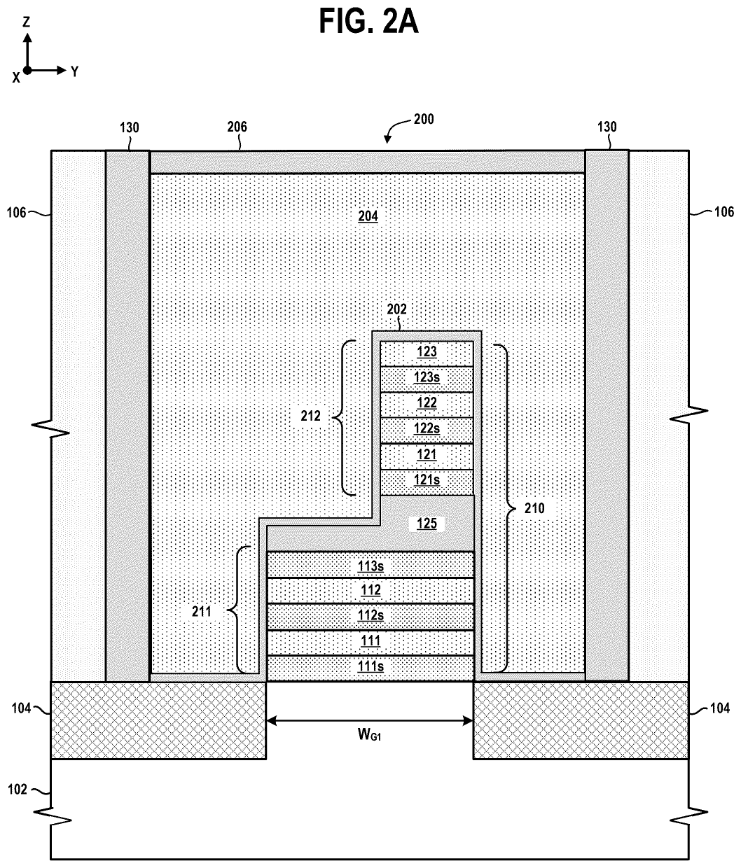

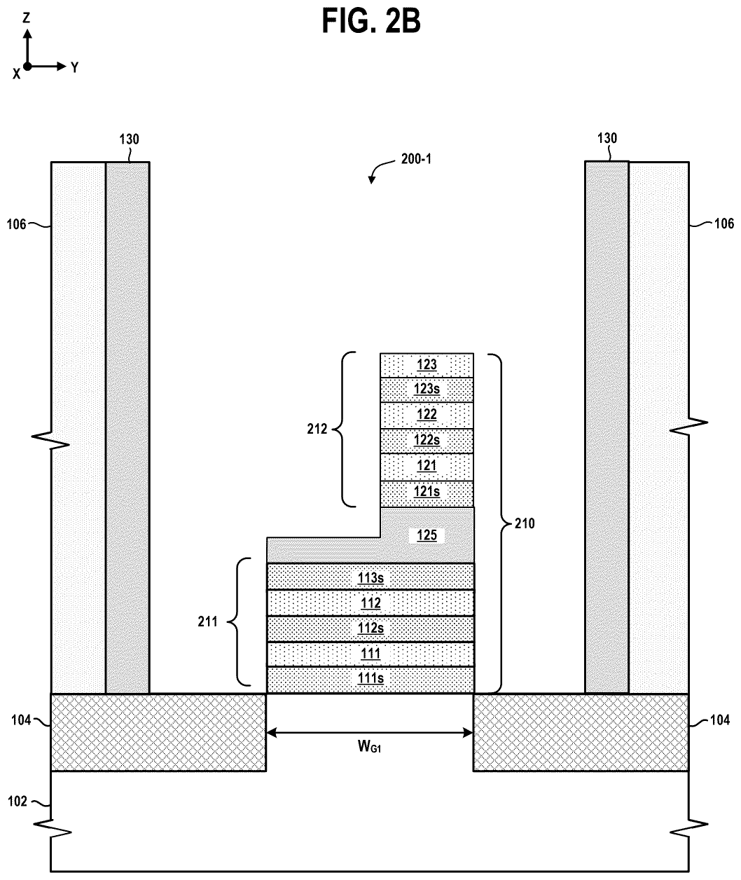

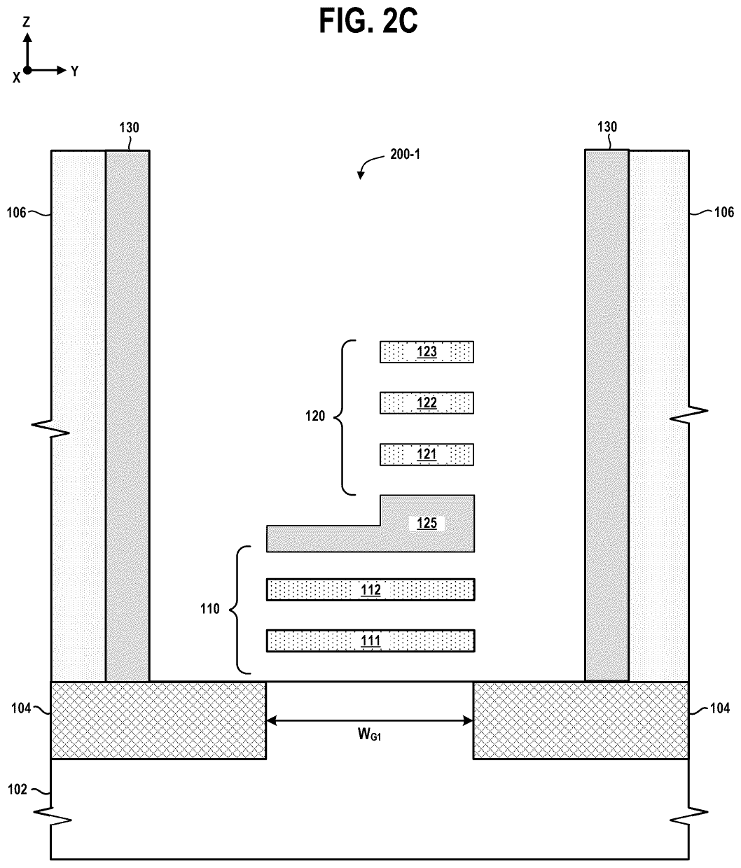

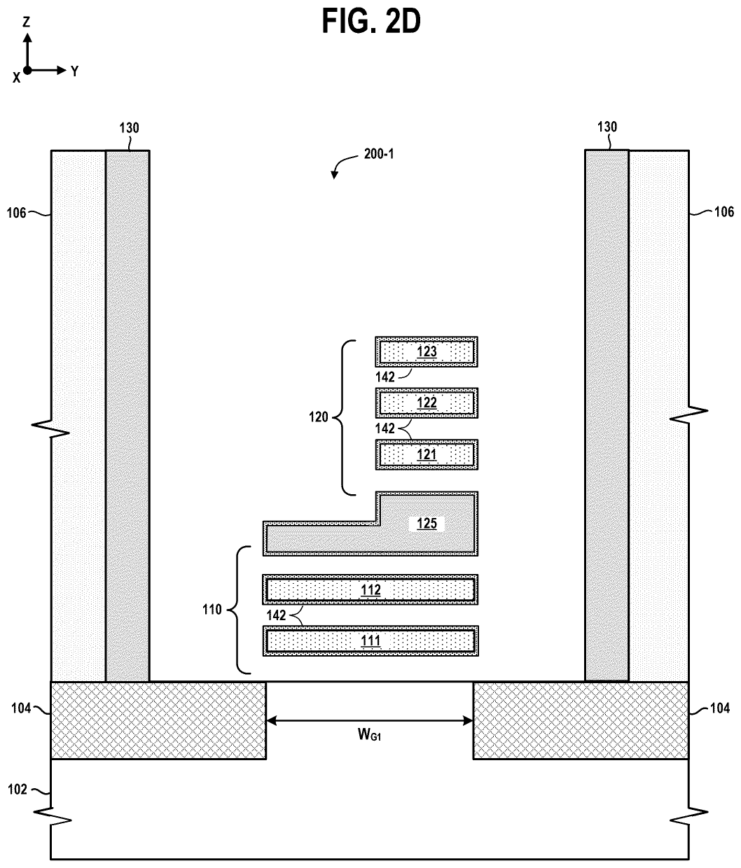

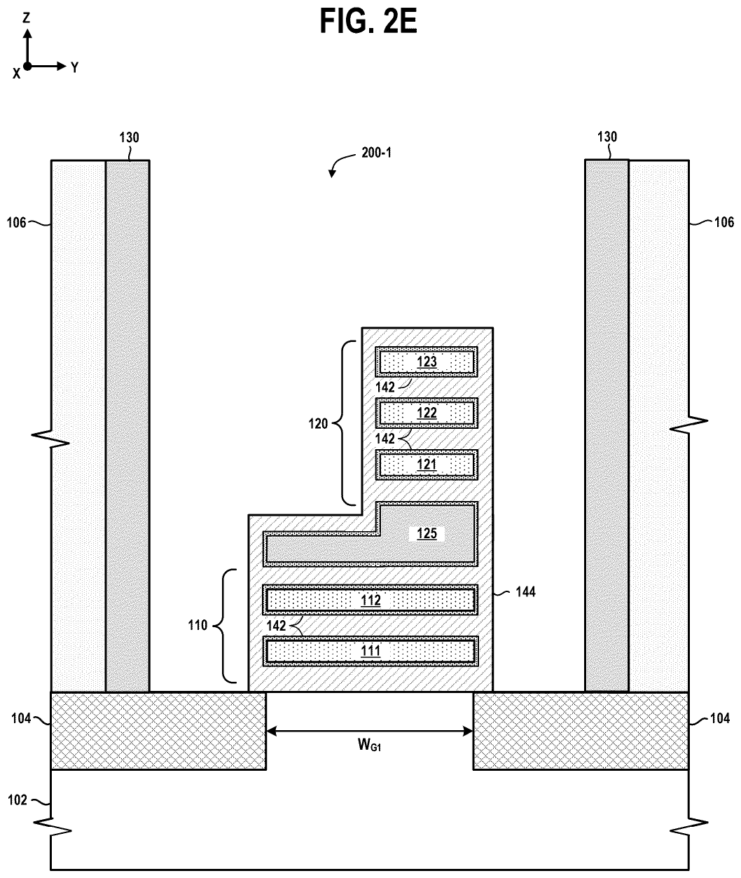

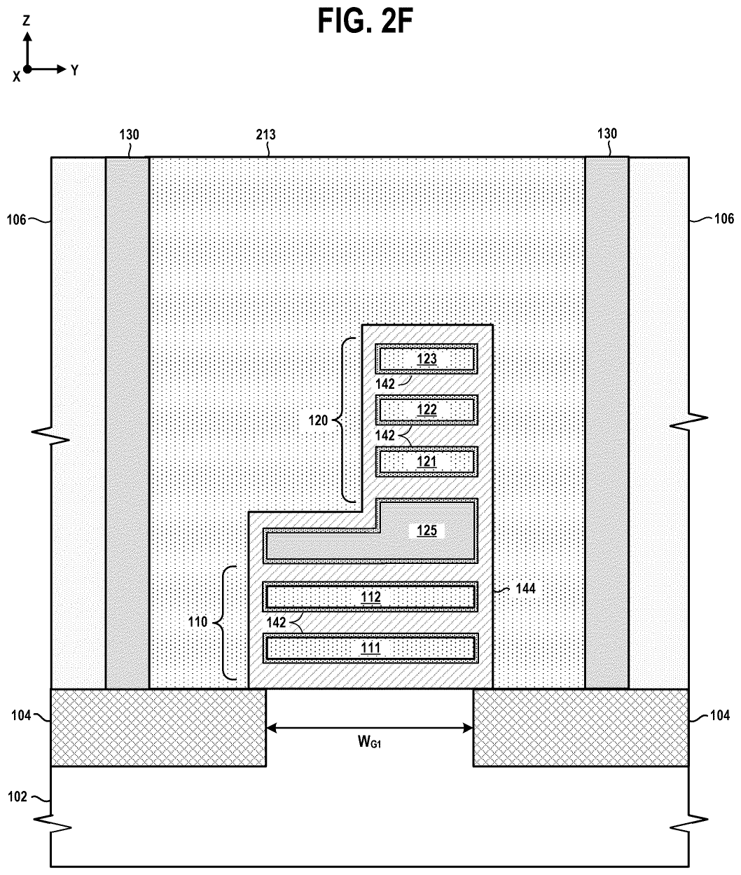

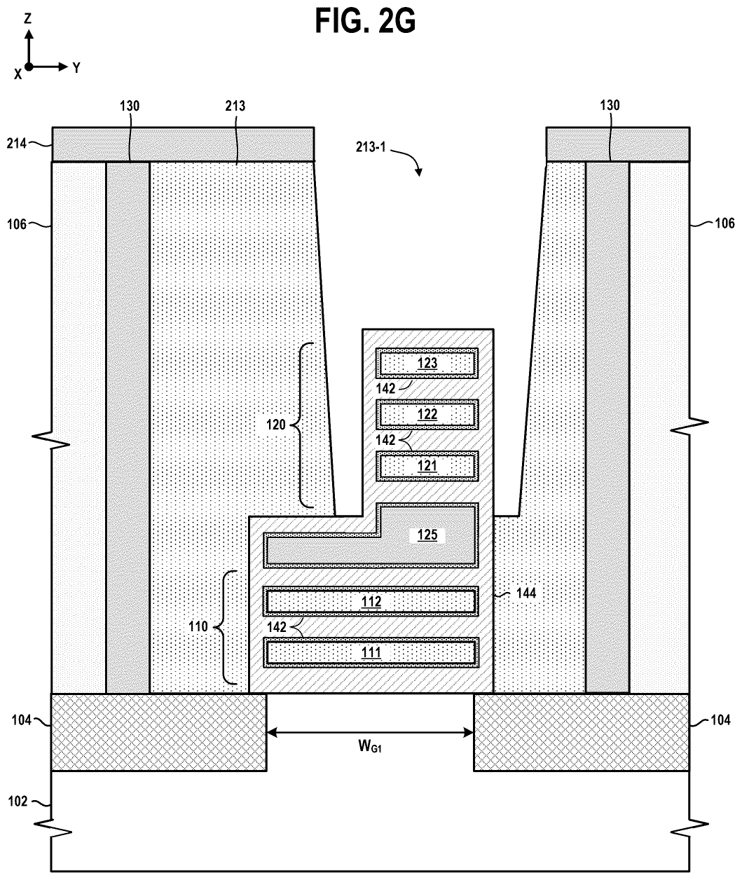

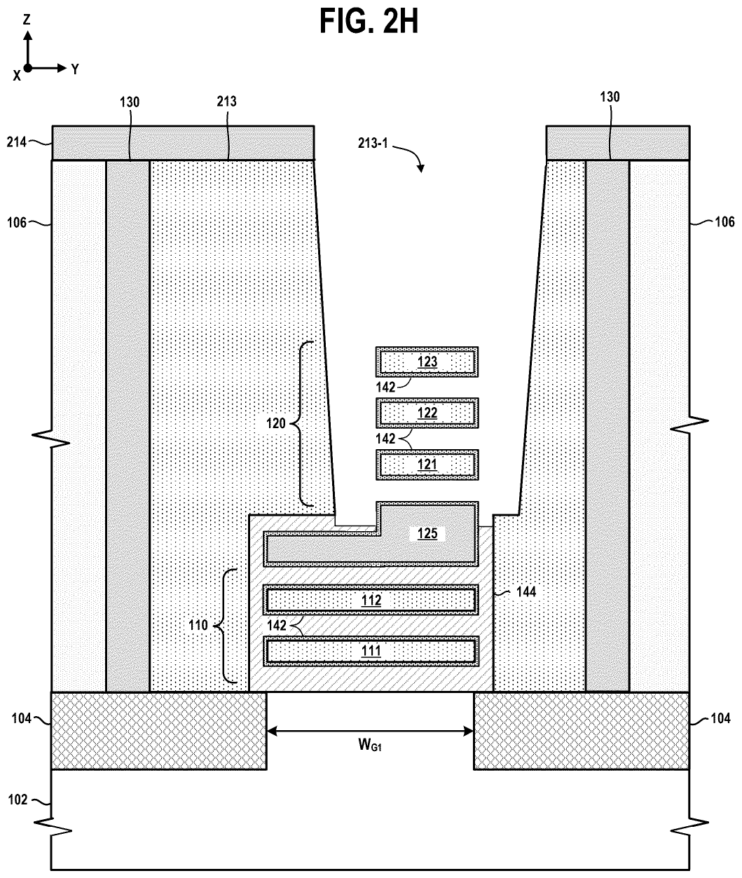

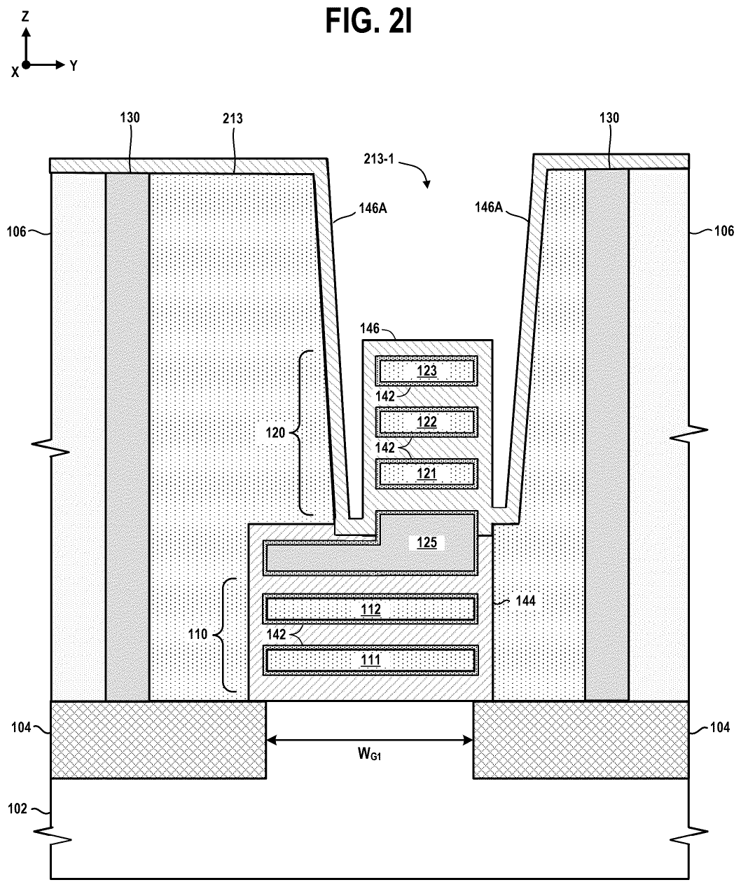

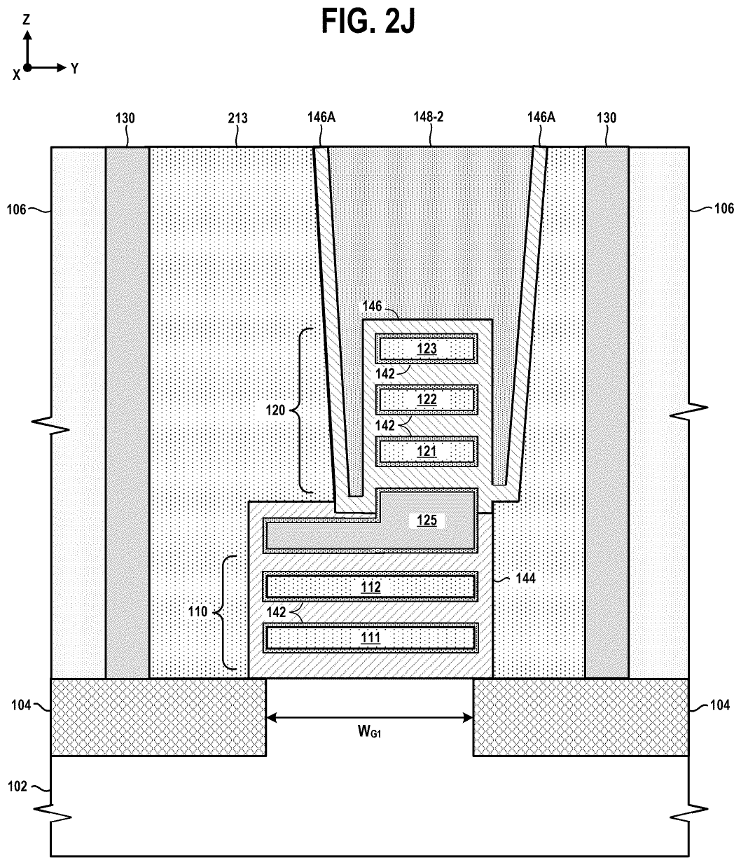

FIGS. 2A-2K schematically illustrate a method for fabricating a semiconductor integrated circuit device comprising a stacked complementary transistor structure, according to an embodiment of the disclosure. In particular, FIGS. 2A-2K schematically illustrate a method for fabricating the semiconductor integrated circuit device 100 of FIGS. 1A-1C. To begin, FIG. 2A is a schematic cross-sectional side view (Y-Z plane) of an intermediate structure of the semiconductor integrated circuit device 100 which comprises a dummy gate 200 (e.g., a polysilicon gate) that is to be replaced with the metal gate 140 by performing an exemplary replacement metal gate (RMG) process. The dummy gate 200 comprises a conformal oxide layer 202 and a dummy gate electrode layer 204 which is formed of a sacrificial material such as polysilicon or amorphous silicon material. In addition, the gate structure shown in FIG. 2A further comprises a gate capping layer 206 (or hard mask layer) which is disposed on the dummy gate electrode layer 204. The gate capping layer 206 has a footprint area which corresponds to and defines the footprint area of the dummy gate electrode layer 204.

The intermediate structure of the semiconductor integrated circuit device 100 as shown in FIG. 2A further comprises a patterned stack of epitaxial semiconductor layers 210 which comprises a first stack of epitaxial semiconductor layers 211, a second stack of epitaxial semiconductor layers 212, and an MDI layer 125 disposed between the first and second stacks of epitaxial semiconductor layers 211 and 212. The first stack of epitaxial semiconductor layers 211 comprises a stack of alternating epitaxial semiconductor channel and sacrificial layers, including the channel layers 111 and 112 of the first transistor 110, and sacrificial layers 111s, 112s, and 113s. The sacrificial layer 111s is disposed between the substrate 102 and the channel layer 111, the sacrificial layer 112s is disposed between the channel layers 111 and 112, and the sacrificial layer 113s is disposed between the channel layer 112 and the MDI layer 125. Similarly, the second stack of epitaxial semiconductor layers 212 comprises a stack of alternating epitaxial semiconductor channel and sacrificial layers, including the channel layers 121, 122, and 123 of the second transistor 120, and sacrificial layers 121s, 122s, and 123s. The sacrificial layer 121s is disposed between the MDI layer 125 and the channel layer 121, the sacrificial layer 122s is disposed between the channel layers 121 and 122, and the sacrificial layer 123s is disposed between the channel layers 122 and 123.

As is known in the art, an epitaxial semiconductor material is a single-crystal (or monocrystalline) semiconductor material that is grown using an epitaxy process. In some embodiments, the epitaxial semiconductor layers of first and second stacks of epitaxial semiconductor layers 211 and 212 comprise single-crystalline semiconductor materials, which are epitaxially grown using known methods such as chemical vapor deposition (CVD), metal-organic chemical vapor deposition (MOCVD), low pressure chemical vapor deposition (LPCVD), molecular beam epitaxy (MBE), vapor-phase epitaxy (VPE), liquid-phase epitaxy (LPE), metal organic molecular beam epitaxy (MOMBE), rapid thermal chemical vapor deposition (RTCVD), low-energy plasma deposition (LEPD), ultra-high vacuum chemical vapor deposition (UHVCVD), atmospheric pressure chemical vapor deposition (APCVD), or other known epitaxial growth techniques which are suitable for the given process flow.

In some embodiments, the channel layers 111, 112, 121, 122, and 123 of the first and second transistors 110 and 120 are formed of a first type of epitaxial semiconductor material, while the sacrificial layers 111s, 112s, 113s, 121s, 122s, and 123s are formed of a second type of epitaxial semiconductor material, which can be etched selective to the first type of epitaxial semiconductor material to thereby “release” the channel layers 111, 112, 121, 122, and 123, in a subsequent stage of fabrication. For example, in some embodiments, the channel layers 111, 112, 121, 122, and 123 of the first and second transistors 110 and 120 are formed of epitaxial (single-crystalline) silicon (or mono-Si), while the sacrificial layers 111s, 112s, 113s, 121s, 122s, and 123s are formed of an epitaxial (single-crystalline) silicon-germanium (SiGe) alloy. This allows the epitaxial SiGe material of the sacrificial layers 111s, 112s, 113s, 121s, 122s, and 123s to be etched selective to the epitaxial Si material of the channel layers 111, 112, 121, 122, and 123 in a subsequent process step to “release” the channel layers 111, 112, 121, 122, and 123 of the first and second transistors 110 and 120. In other embodiments, the channel layers 111, 112, 121, 122, and 123 of the first and second transistors 110 and 120 can be formed of an epitaxial SiGe material with a desired Ge concentration (optimized for device performance), while the sacrificial layers 111s, 112s, 113s, 121s, 122s, and 123s are formed of, e.g., epitaxial silicon.

It is to be noted that the intermediate structure shown in FIG. 2A can be fabricated using suitable semiconductor fabrication process modules and materials. The substrate 102 may comprise one or more of various types of semiconductor substrate structures and materials. For example, in some embodiments, the substrate 102 comprises a bulk semiconductor substrate (e.g., wafer) that is formed of monocrystalline semiconductor material including, but not limited to, silicon, germanium, or other types of semiconductor substrate materials that are commonly used in bulk semiconductor fabrication processes such as a SiGe alloy, silicon germanium carbide (SiGeC), silicon carbide (SiC), III-V semiconductor materials such as gallium arsenide (GaAs), gallium nitride (GaN), etc. In other embodiments, the substrate 102 may be an active semiconductor layer of an SOI (silicon-on-insulator) substrate, a germanium-on-insulator (GeOI) substrate, or another type of semiconductor-on-insulator substrate.

At an early stage of fabrication, the patterned stack of epitaxial semiconductor layers 210 is formed on the substrate 102 by sequentially depositing layers of epitaxial material over the substrate 102, and then performing one or more lithographic patterning processes to pattern the deposited layers of epitaxial material (via dry etch processes such as reactive ion etch (RIE) processes) to thereby form the patterned stack of epitaxial semiconductor layers 210. In addition, the substrate 102 is lithographically patterned to form an STI trench around the patterned stack of epitaxial semiconductor layers 210, and the STI trench is filled with one or more layers of insulating material to form the STI layer 104. In some embodiments, the patterning process results in the bottom portion of the patterned stack of epitaxial semiconductor layers 210 having a width (in Y direction) that defines the gate width Wai of the first transistor 110, and an initial stack length L_{S} (in the X direction, as shown in FIG. 1B) which defines an overall target length L of the gate structure plus source/drains regions of the substrate 102 on opposing sides of the gate structure.

A next stage of the fabrication process comprises constructing the dummy gate 200 which is surrounded by the gate sidewall spacer 130. In some embodiments, the dummy gate 200 is formed by a process which comprises (i) depositing a thin conformal oxide layer (e.g., conformal layer of silicon dioxide) over the entire surface of the semiconductor substrate, (ii) depositing a blanket layer of polysilicon (or alternatively, amorphous silicon) over the conformal oxide layer, (iii) planarizing the blanket layer of polysilicon using, e.g., a chemical mechanical polishing (CMP) process, and (iv) lithographically patterning the planarized layer of polysilicon and the conformal oxide layer to form the conformal oxide layer 202 and the dummy gate electrode layer 204 of the dummy gate 200.

In some embodiments, the lithographic patterning process to form the dummy gate 200 comprises forming a hard mask layer on the planarized surface of the polysilicon layer by depositing a layer of dielectric material or multiple layers of dielectric materials including, but not limited to such as silicon nitride (SIN), silicon boron carbide nitride (SiBCN), silicon oxycarbonitride (SiOCN), etc., and patterning the hard mask layer to form the gate capping layer 206 which defines a footprint image of dummy gate 200 (and thus the subsequently formed metal gate 140). For example, in some embodiments, the gate capping layer 206 has a footprint arca defined by a width W in the Y-direction (FIG. 1A), and a length of Lo in the X-direction (FIG. 1B). The gate capping layer 206 is then utilized as an etch hard mask to anisotropically etch (e.g., RIE) the sacrificial polysilicon and oxide layers down to the upper surface of the substrate 102 to thereby form the dummy gate 200 which covers the patterned stack of epitaxial semiconductor layers 210, except for portions of the patterned stack of epitaxial semiconductor layers 210 that extend from the dummy gate 200 in the X-direction (given that the initial stack length L_{S} of the patterned stack of epitaxial semiconductor layers 210 in the X-direction is initially longer than the length L_{G} of the dummy gate 200 in the X-direction.

The gate sidewall spacer 130 is then formed by depositing a conformal layer of dielectric material over the entire surface of the semiconductor structure. The conformal layer of dielectric material can be formed of SiN, SiBCN, SiCON, or any other type of low-k dielectric material that is commonly used to form insulating gate sidewall spacers of FET devices (e.g., a low-k dielectric material having a k of less than 5, wherein k is the relative dielectric constant), and deposited using known techniques such as atomic layer deposition (ALD), chemical vapor deposition (CVD), or physical vapor deposition (PVD). The conformal layer of dielectric material is then patterned by performing an anisotropic dry etch process (e.g., RIE process), to selectively etch down the conformal layer of dielectric material in a vertical direction (Z-direction), which results in the formation of the gate sidewall spacer 130 that surrounds the dummy gate 200 and defines the footprint region of the metal gate 140. This etch process is performed selective to the semiconductor materials of the patterned stack of epitaxial semiconductor layers 210 and the STI layer 104.

In some embodiments, after forming the gate sidewall spacer 130, an anisotropic dry etch process (e.g., RIE) is performed to etch down the exposed portions of the patterned stack of epitaxial semiconductor layers 210 which extend past the gate sidewall spacer 130 in the X-direction. This etch process serves to reduce the length of the patterned stack of epitaxial semiconductor layers 210 from the initial stack length Ls to the length L, where the length ends of the channel layers 111, 112, 121, 122, and 123 and the sacrificial layers 111s, 112s, 113s, 121s, 122s, and 123s of the patterned stack of epitaxial semiconductor layers 210 are essentially coplanar with the outer vertical sidewall surfaces of the gate sidewall spacer 130 in the X-direction.

A next step in the fabrication process comprises laterally recessing (in the X-direction) exposed sidewall surfaces of the sacrificial layers 111s, 112s, 113s, 121s, 122s, and 123s of the patterned stack of epitaxial semiconductor layers 210 to form recesses at a depth which corresponds to a thickness of the gate sidewall spacer 130, and then filling such recesses with dielectric material to form the embedded gate sidewall spacers 132 as shown in FIG. 1B. In some embodiments, the lateral etch process can be performed using an isotropic wet etch process with an etch solution that is suitable to etch the semiconductor material (e.g., SiGe) of the sacrificial layers 111s, 112s, 113s, 121s, 122s, and 123s selective to the semiconductor material (e.g., Si) of the channel layers 111, 112, 121, 122, and 123 of the first and second transistors 110 and 120.

The gate sidewall spacers 132 are then formed within the recesses by a process which comprises depositing a conformal layer of dielectric material until the recesses are filled with dielectric material, and performing an etch back process to remove the excess dielectric material from the gate structure and the substrate. The embedded gate sidewall spacers 132 can be formed of the same or similar dielectric material as the gate sidewall spacer 130 (e.g., SiN, SiBCN, SiCO, SiBCN, SiCON), or any other type of low-k dielectric material. The dielectric material can be deposited using a highly conformal deposition process, such as ALD, to ensure that the recesses are sufficiently filled with dielectric material. The conformal layer of dielectric material can be etched back using an isotropic (wet or dry) etch process to remove the excess dielectric material, while leaving the dielectric material in the recesses to form the gate sidewall spacers 132. The wet etch process may include, but is not limited to, buffered hydrofluoric acid (BHF), diluted hydrofluoric acid (DHF), hydrofluoric nitric acid (HNA), phosphoric acid, HF diluted by ethylene glycol (HFEG), hydrochloric acid (HCl), or any combination thereof.

A next step in the fabrication process comprises forming the first and second source/drain elements 118-1 and 118-2 of the first transistor 110, followed by forming the first and second source/drain elements 128-1 and 128-2 of the second transistor 120, by utilizing epitaxial growth techniques. The types of epitaxial semiconductor materials that are utilized to form the first and second source/drain elements 118-1 and 118-2 of the first transistor 110 will depend on whether the first transistor 110 is a N-type MOSFET or P-type MOSFET. For example, in an exemplary embodiment where the first transistor 110 is a N-type MOSFET and the second transistor 120 is a P-type MOSFET, and where the channel layers 111, 112, 121, 122, and 123 are formed of epitaxial Si, (i) the first and second source/drain elements 118-1 and 118-2 of the first transistor 110 can be formed of carbon-doped silicon (Si:C) epitaxial material, or phosphorus-doped silicon (Si:P) epitaxial material, or other suitable epitaxial materials for N-type MOSFET devices, and (ii) the first and second source/drain elements 128-1 and 128-2 of the second transistor 120 can be formed of an epitaxial SiGe material (with a relatively high Ge concentration), or a boron-doped SiGe (B:SiGe) epitaxial material, or other suitable epitaxial materials for P-type MOSFET devices.

It is to be noted that the source/drain elements can be formed using various techniques known to those of ordinary skill in the art. For example, in some embodiments, the first and second source/drain elements 118-1 and 118-2 of the first transistor 110 can be epitaxially grown bottom up starting on, e.g., the exposed <100>crystalline silicon surface of the substrate 102 as a seed surface. With this process, the epitaxial process is configured so that a growth rate of the epitaxial material on the <100> crystalline plane surface of the substrate is greater than a growth rate of the epitaxial material on the exposed side surfaces of the channel layers 111, 112, 121, 122, and 123 of the first and second transistors 110 and 120, which have a <110> crystalline plane orientation. In this process, the substrate surface provides a <100> semiconductor surface to seed the growth of the epitaxial material which form the first and second source/drain elements 118-1 and 118-2, wherein the deposited epitaxial semiconductor material takes on the same lattice structure and orientation of the crystalline seed surface.

In other embodiments, the first and second source/drain elements 118-1 and 118-2 of the first transistor 110 can be epitaxially grown starting on the exposed sidewall surfaces of the channel layers 111 and 112 which provide the surface area to seed the epitaxial growth of the first and second source/drain elements 118-1 and 118-2. In some embodiments, the epitaxial growth of the semiconductor material is performed so that the epitaxial material merges (in the Z-direction) to form the first and second source/drain elements 118-1 and 118-2 of the first transistor 110. With this process, the exposed sidewall surfaces of the channel layers 121, 122, and 123 of the second transistor 120 are covered with insulating/dielectric material using known techniques to prevent epitaxial growth on the exposed sidewall surfaces of the channel layers 121, 122, and 123 during the epitaxial process to grow the first and second source/drain elements 118-1 and 118-2 of the first transistor 110.

Next, the first and second source/drain elements 128-1 and 128-2 of the second transistor 120 can formed by epitaxially growing semiconductor material on the exposed sidewall surfaces of the channel layers 121, 122, and 123. In this process, exposed sidewall surfaces of the channel layers 121, 122, and 123 provide a surface area to seed the epitaxial growth of the first and second source/drain elements 128-1 and 128-2. In some embodiments, the epitaxial growth of the semiconductor material is performed so that the epitaxial material merges (in the Z-direction) to form the first and second source/drain elements 128-1 and 128-2 of the second transistor 120.

It is to be noted that prior to forming the first and second source/drain elements 128-1 and 128-2 of the second transistor 120, the first and second source/drain elements 118-1 and 118-2 of the first transistor 110 are covered by insulating material to protect the first and second source/drain elements 118-1 and 118-2 from damage and/or additional growth of epitaxial material during the formation of the first and second source/drain elements 128-1 and 128-2 of the second transistor 120. For example, a conformal dielectric protective liner can be conformally formed on the first and second source/drain elements 118-1 and 118-2 and/or an initial shallow layer of the pre-metallization dielectric layer 106 can be formed to cover the first and second source/drain elements 118-1 and 118-2 during the during the epitaxial process to grow the first and second source/drain elements 128-1 and 128-2 of the second transistor 120.

Following the formation of the first and second source/drain elements 128-1 and 128-2 of the second transistor 120, the process flow continues with forming the pre-metallization dielectric layer 106, prior to commencing the replacement metal gate process. In some embodiments, the pre-metallization dielectric layer 106 is formed by depositing a blanket layer of dielectric/insulating material over the semiconductor structure and planarizing the layer of dielectric/insulating material down to the gate capping layer. The pre-metallization dielectric layer 106 may comprise any suitable insulating/dielectric material that is commonly utilized in semiconductor process technologies including, but not limited to, silicon oxide, silicon nitride, silicon oxynitride, SiCOH, SiCH, SiCNH, or other types of silicon-based low-k dielectrics (e.g., k less than about 4.0), porous dielectrics, known ULK (ultra-low-k) dielectric materials (with k less than about 2.5), or any suitable combination of those materials. The dielectric/insulating material of the pre-metallization dielectric layer 106 is deposited using known deposition techniques, such as, for example, ALD, CVD, PECVD, PVD, or spin-on deposition. In some embodiments, the layer of dielectric/insulating material is planarized using a standard planarization process such as CMP to remove the overburden dielectric/insulating down to the upper surface of the gate capping layer 206. In some embodiments, a conformal layer of dielectric material (e.g., SiN) is deposited (prior to depositing the insulating material of pre-metallization dielectric layer 106 to form a protective liner layer which covers source/drain elements of the first and second transistors 110 and 120, before blanket depositing the insulating material to form the pre-metallization dielectric layer 106.

Following the formation of the pre-metallization dielectric layer 106, the exemplary replacement metal gate process is performed to replace the dummy gate 200 with the metal gate 140, using the exemplary process flow schematically illustrated in FIGS. 2B-2K. For example, FIG. 2B is a schematic cross-sectional side view of an intermediate structure of the semiconductor integrated circuit device 100 which is obtained after removing the dummy gate 200 to form an open gate region 200-1 which exposes the patterned stack of epitaxial semiconductor layers 210. In some embodiments, the dummy gate 200 is removed using a process flow which comprises removing the gate capping layer 206 to expose the dummy gate 200, and performing several etch processes to remove the dummy gate 200.

For example, in some embodiments, the gate capping layer 206 is removed by planarizing (e.g., via CMP) the surface of the semiconductor structure down to an upper surface of the dummy gate electrode layer. In other embodiments, the dielectric material of the gate capping layer 206 (e.g., SiN) can be etched away selective to the materials of the gate sidewall spacer 130 (e.g., SiBCN) and the pre-metallization dielectric layer 106 to expose the underlying dummy gate electrode layer 204. The dummy gate electrode layer 204 (e.g., polysilicon layer) is removed using a selective dry etch or wet etch process with suitable etch chemistries, including ammonium hydroxide (NH₄OH), tetramethylammonium hydroxide (TMAH), or SF6 plasma. The etching of the dummy gate electrode layer 204 is selective to, e.g., the conformal oxide layer 202 of the dummy gate, to thereby protect the patterned stack of epitaxial semiconductor layers 210 from being etched during the etch. After the polysilicon layer is removed, an oxide etch process is performed to etch away the conformal oxide layer 202 selective to the materials of the patterned stack of epitaxial semiconductor layers 210. In this manner, the sacrificial materials (e.g., dummy polysilicon and oxide layers) of the dummy gate 200 can be etched away to expose the patterned stack of epitaxial semiconductor layers 210 and without damaging the channel layers 111, 112, 121, 122, and 123.

Next, FIG. 2C is a schematic cross-sectional side view of an intermediate structure of the semiconductor integrated circuit device 100 which is obtained after selectively etching the sacrificial layers 111s, 112s, 113s, 121s, 122s, and 123s of the patterned stack of epitaxial semiconductor layers 210 to release the channel layers 111, 112, 121, 122, and 123 of the first and second transistors 110 and 120. For example, in exemplary embodiments where the sacrificial layers 111s, 112s, 113s, 121s, 122s, and 123s are formed of an epitaxial SiGe material, and the channel layers 111, 112, 121, 122, and 123 are formed of epitaxial Si material, the sacrificial layers 111s, 112s, 113s, 121s, 122s, and 123s can be selectively etched (with high etch selectivity) via an isotropic dry etch process (e.g., a gas phase HCl (hydrochloric acid) etch) or an isotropic wet etch process (e.g., a wet etch solution containing hydrogen peroxide (H₂O₂)) to etch the SiGe material of the sacrificial layers selective to the Si material of the channel layers 111, 112, 121, 122 and 123. A vapor phase HCL gas isotropic etch process provides high etch selectivity when, for example, the channel layers 111, 112, 121, 122, and 123 are formed of epitaxial Si or an epitaxial SiGe with a lower Ge concentration than the epitaxial SiGe material of the sacrificial layers 111s, 112s, 113s, 121s, 122s, and 123s.

Next, FIG. 2D is a schematic cross-sectional side view of an intermediate structure of the semiconductor integrated circuit device 100 which is obtained after forming high-k dielectric layers 142 on exposed surfaces of the channel layers 111, 112, 121, 122, and 123. In some embodiments, a process for forming the high-k dielectric layers 142 comprises (i) performing a channel pre-clean process to clean the exposed epitaxial silicon surfaces of the channel layers 111, 112, 121, 122, and 123, (ii) forming ultra-thin interfacial layers on the exposed epitaxial silicon surfaces of the channel layers 111, 112, 121, 122, and 123, and (iii) depositing a high-k dielectric material to form the high-k dielectric layers 142.

In some embodiments, the ultra-thin interfacial layers are formed by performing an oxidation process to grow ultra-thin interfacial silicon oxide layers on the exposed surfaces of the channel layers 111, 112, 121, 122, and 123. For example, in some embodiments, the interfacial silicon oxide layers are formed using a chemical oxidation process in an ozonated deionized water comprising ozone, and a suitable oxidation temperature, ozone concentration in the deionized water, and chemical oxidation process time to form thin interfacial silicon oxide layers (e.g., silicon dioxide layers). In some embodiments, the ultra-thin interfacial layers of silicon oxide are formed with a thickness in a range of about 1 angstrom to about 10 angstroms (i.e., about 0.1 nm to about 1 nm).

In some embodiments, the high-k dielectric layers 142 are formed by depositing one or more conformal layers of high-k gate dielectric material over the exposed surfaces of the semiconductor structure to conformally cover the surfaces of the channel layers 111, 112, 121, 122, and 123. In some embodiments, the high-k gate dielectric layers 142 are preferably formed of a high-k dielectric material having a dielectric constant of about 3.9 or greater. For example, the gate dielectric material can include but is not limited to metal oxides such as hafnium oxide, hafnium silicon oxide, hafnium silicon oxynitride, hafnium zirconium oxide, and nitride films thereof. In other embodiments, the high-k dielectric may comprise lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k dielectric material may further include dopants such as lanthanum, aluminum. In some embodiments, the conformal high-k gate dielectric layers 142 are formed with a thickness in a range of about 0.5 nm to about 2.0 nm, which will vary depending on the target application. The conformal layer of high-k gate dielectric material is deposited using known methods such as ALD, for example, which allows for high conformality of the gate dielectric material.

Next, FIG. 2E is a schematic cross-sectional side view of an intermediate structure of the semiconductor integrated circuit device 100 which is obtained after depositing one or more layers of work function metal to form the first work function metal layer 144 which initially encapsulates the channel layers 111, 112, 121, 122, and 123 and the MDI layer 125. In some embodiments, the first work function metal layer 144 is formed of one or more layers of work function metal to ensure desired electrical properties of the metal gate for the first transistor 110. For example, in some embodiments where the first transistor 110 is an N-type MOSFET, the first work function metal layer 144 is engineered to ensure that the channel layers 111 and 112 of the first transistor effectively operate as an N-doped channel. In some embodiments, the first work function metal layer 144 is formed of titanium nitride (TiN). In some embodiments, the first work function metal layer 144 comprises multiple layers of work function metals including, for example, two layers of TiN with a layer of titanium aluminum carbide (TiAlC) disposed between the two layers of TiN (e.g., a trilayer stack of TiN/TiAlC/TiN work function metals). It is to be noted that other types of work function metals or metal alloys can be utilized to form the first work function metal layer 144, which are suitable for the given type (e.g., N-type) of the first transistor 110.

The work function metal layers are conformally deposited using known methods such as ALD, CVD, etc., which allow for high conformality of the deposited work function metal layers. As schematically shown in FIG. 2E, the work function metal layer(s) completely fill the spaces above and below the channel layers 111, 112, 121, 122, and 123. Indeed, in instances where the initial spacing between the channel layers 111, 112, 121, 122, and 123 is relatively small (e.g., 7 nm to 10 nm), after formation of the high-k dielectric layers 142, the conformal deposition of a stack of two or more work function metal layers can result in filling (i.e., pinch-off) the spaces above and below the channel layers 111, 112, 121, 122, and 123 such that the spaces are filled with gate dielectric material and work function metal. This is sufficient for short-channel length nanosheet MOSFET devices where L_{G} is about 15 nm or less.

It is to be noted that while not specifically shown in FIG. 2E, as a result of the conformal deposition processes, the deposited gate dielectric material (FIG. 2D) and work function metal would conformally line the bottom and sidewall surfaces of the open gate region 200-1, as well as line the upper surface of the pre-metallization dielectric layer 106. However, for case of illustration, such portions of the conformally deposited high-k dielectric material and work function metal are not shown in FIG. 2E as lining the bottom and sidewall surfaces of the open gate region 200-1 and the upper surface of the pre-metallization dielectric layer 106.

Next, FIG. 2F is a schematic cross-sectional side view of an intermediate structure of the semiconductor integrated circuit device 100 which is obtained after depositing a layer of sacrificial material 213 to fill the open gate region 200-1. In some embodiments, the layer of sacrificial material 213 comprise amorphous silicon (a-Si). The layer of sacrificial material 213 is formed by blanket depositing a layer of amorphous silicon to fill the open gate region 200-1. A CMP process is then performed to planarize the surface of the semiconductor structure down to the pre-metallization dielectric layer 106, thereby removing overburden portions of the layers of the sacrificial material, the work function metal, and the high-k dielectric material on the upper surface of the pre-metallization dielectric layer 106, resulting in the intermediate structure shown in FIG. 2F.

A reliability thermal anneal process is then performed to thermally anneal the intermediate structure shown in FIG. 2F. For example, in some embodiments, a spike rapid thermal anneal (spike RTA) is performed to optimize certain electrical characteristics of various device components. For example, the spike RTA is configured to improve the quality of the interface between the ultra-thin interfacial layers and high-k dielectric layers 142. In addition, the spike RTA is configured to activate dopants in the source/drain elements of the first and second transistors 110 and 120 and cause dopants to be injected into the end portions of the channel layers 111, 112, 121, 122, and 123 that are in contact with the epitaxial semiconductor material of source/drain elements, which effectively results in extending the source/drain elements into the semiconductor material of the end portions of the channel layers 111, 112, 121, 122, and 123 and thereby decrease parasitic resistance of the nanosheet FET device. Moreover, the spike RTA is configured to enhance the characteristics of the first work function metal layer 144 of the metal gate of the first transistor 110.

In some embodiments the spike RTA is performed at a peak temperature of about 900° C. to about 1000° C. (e.g., 970° C.) and for a time period ranging from about 0.001 to about 1 second. The semiconductor structure is rapidly heated to the target peak temperature (typically in milliseconds) during a ramp-up phase. After reaching the peak temperature, the semiconductor structure is rapidly cooled down (spike anneal), which helps limit the thermal budget. By precisely controlling the temperature profile, spike anneal processes enable precise control over electrical properties of the first and second transistors 110 and 120.

Next, FIG. 2G is a schematic cross-sectional side view of an intermediate structure of the semiconductor integrated circuit device 100 which is obtained after forming a trench opening 213-1 in the layer of sacrificial material 213 to expose a portion of the first work function metal layer 144 which encapsulates the channel layers 121, 122, and 123 of the second transistor 120. In some embodiments, the trench opening 213-1 is formed by performing a lithographic patterning process to form a hard etch mask 214 with an opening that defines an image of the trench opening 213-1 to be formed. An etch process is then performed to etch down an exposed region of the layer of sacrificial material 213 down to a level of the MDI layer 125. In some embodiments, an anisotropic etch process is performed (with a suitable etch chemistry) to etch the layer of sacrificial material 213 selective to the first work function metal layer 144 to form the trench opening 213-1 as shown in FIG. 2G. A timed etch process can be performed to terminate the etch process at a point where the bottom of the trench opening 213-1 reaches the MDI layer 125.

Next, FIG. 2H is a schematic cross-sectional side view of an intermediate structure of the semiconductor integrated circuit device 100 which is obtained after removing the portion of the first work function metal layer 144 which is exposed by the trench opening 213-1. The exposed portion of the first work function metal layer 144 is etched selective to the materials of the layer of sacrificial material 213 and the high-k dielectric layers 142 to remove the portion of the first work function metal layer 144 surrounding the channel layers 121, 122, and 123 of the second transistor 120. The first work function metal layer 144 can be removed using any suitable isotropic etch process with an etch chemistry that is configured to etch the first work function metal layer 144 highly selective to the materials of the layer of sacrificial material 213 and the high-k dielectric layers 142.

Next, FIG. 2I is a schematic cross-sectional side view of an intermediate structure of the semiconductor integrated circuit device 100 which is obtained after conformally depositing one or more layers of work function metal to form the second work function metal layer 146 which encapsulates the channel layers 121, 122, and 123 of the second transistor 120. In some embodiments, the second work function metal layer 146 is formed of TiN, with a thickness of about 2 nm, or other types of work functions metals that are suitable to obtain desired electrical characteristics of the metal gate for the second transistor 120 (e.g., P-type MOSFET). As schematically shown in FIG. 2I, the conformal deposition of the one or more layers of work function metal results in the formation of a thin residual layer 146A of the second work function metal layer 146 on sidewalls of the trench opening 213-1 of the layer of sacrificial material 213.

Next, FIG. 2J is a schematic cross-sectional side view of an intermediate structure of the semiconductor integrated circuit device 100 which is obtained after filling the trench opening 213-1 (in the layer of sacrificial material 213) with a low-resistance metallic material to form the second metal gate electrode 148-2 in contact with the second work function metal layer 146 of the second transistor 120. In some embodiments, the low-resistance metallic material comprises tungsten. In other embodiments, the low-resistance metallic material may comprise, e.g., ruthenium, cobalt, copper, aluminum, etc. In some embodiments, the second metal gate electrode 148-2 is formed by depositing a layer of low-resistance metallic material to fill the trench opening 213-1 using any suitable metal deposition process, followed by performing a CMP process to remove the overburden low-resistance metallic material and work function metal on the upper surface of the pre-metallization dielectric layer 106, resulting in the intermediate semiconductor device structure shown in FIG. 2J.

Next, FIG. 2K is a schematic cross-sectional side view of an intermediate structure of the semiconductor integrated circuit device 100 which is obtained after removing a remaining portion of the layer of sacrificial material 213 to form an open gate region 213-2 and thereby expose the first work function metal layer 144 of the first transistor 110. In some embodiments, a wet etch process is performed to remove the remaining portion of the layer of sacrificial material 213 selective to the first work function metal layer 144 and the materials of other surrounding elements (e.g., elements 106, 130, 146A, 148-2, etc.). For example, in some embodiments, the remaining portion of the layer of sacrificial material 213 is removed using a wet etch process comprising hot ammonium hydroxide (NH₄OH).

Following the removal of the remaining portion of the layer of sacrificial material 213, the open gate region 213-2 is filled with a low-resistance metallic material to form the first metal gate electrode 148-1 in contact with the first work function metal layer 144 of the first transistor 110, resulting in the semiconductor integrated circuit device 100 as shown in FIGS. 1A-1C. In some embodiments, the open gate region 213-2 is filled with a low-resistance metallic material such as tungsten, such that the first metal gate electrode 148-1 and the second metal gate electrode 148-2 are formed of the same low-resistance metallic material.

As noted above, the exemplary fabrication process of FIGS. 2A-2K results in the formation of the stacked complementary transistor structure 108 in which the metal gates of the first and second transistors 110 and 120 are merged to form a metal gate 140 (e.g., shared metal gate structure), while the first and second transistors 110 and 120 have separate work function metal layers (e.g., first and second work function metal layers 144 and 146), and a common interfacial layer/high-k dielectric stack. As noted above, since the first metal gate electrode 148-1 and the second metal gate electrode 148-2 are separated by a thin residual layer 146A of the second work function metal layer 146, the first metal gate electrode 148-1 and the second metal gate electrode 148-2 are effectively electrically connected thereby forming the shared metal gate structure of the metal gate 140 of the first and second transistors 110 and 120.

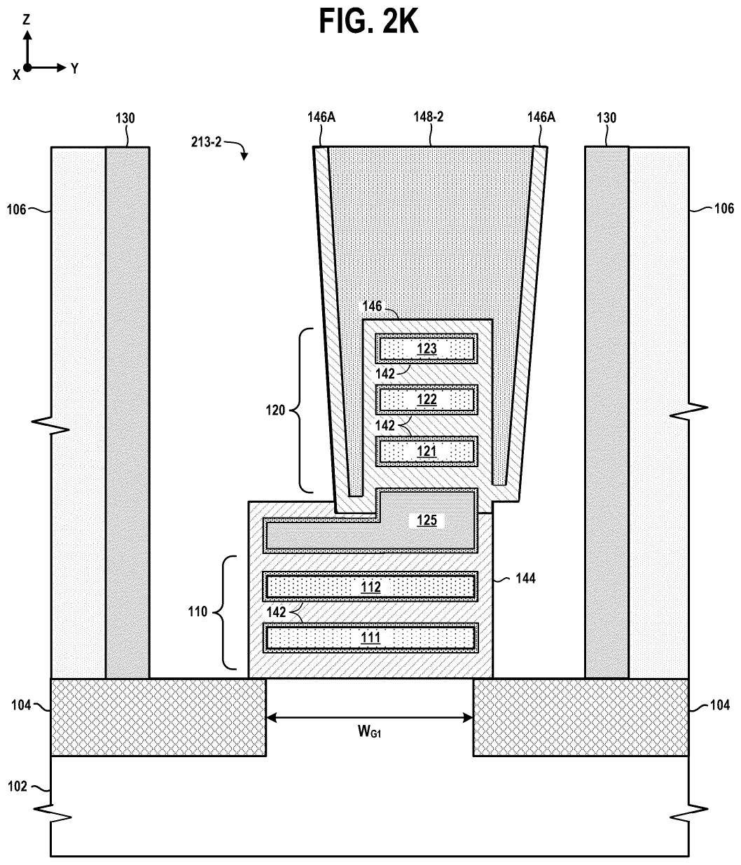

In other embodiments, a stacked complementary transistor structure is constructed to have a split gate structure (or non-shared gate structure) in which the metal gates of the first and second transistors 110 and 120 are not shared, and where the first and second transistors 110 and 120 having separate work function metal layers, and a common interfacial layer/high-k dielectric stack. For example, FIG. 3 is schematic cross-sectional side view (Y-Z plane) of a semiconductor integrated circuit device 300 comprising a stacked complementary transistor structure, according to another exemplary embodiment of the disclosure. In particular, the semiconductor integrated circuit device 300 (or device 300) is similar to the semiconductor integrated circuit device 100 as discussed above in that device 300 comprises the substrate 102, the STI layer 104, the pre-metallization dielectric layer 106, etc. However, the semiconductor integrated circuit device 300 comprises a stacked complementary transistor structure 308 (e.g., stacked complementary FET structure) having a metal gate 340 which comprises a split metal gate structure, as opposed to the stacked complementary transistor structure 108 which comprise the metal gate 140 having a shared metal gate structure of the first and second transistors 110 and 120.

More specifically, the stacked complementary transistor structure 308 is similar to the stacked complementary transistor structure 108 (FIGS. 1A-1C) in that the stacked complementary transistor structure 308 comprises the first transistor 110, and the second transistor 120 disposed over the first transistor 110. In addition, the first transistor 110 comprises the channel layers 111 and 112, and the first and second source/drain elements 118-1 and 118-2 (as shown in FIG. 1B). The second transistor 120 comprises the channel layers 121, 122, and 123, and the first and second source/drain elements 128-1 and 128-2 (as shown in FIG. 1B). The channel layers of the first and second transistors 110 and 120 are separated by the MDI layer 125.

The stacked complementary transistor structure 308 further comprises a gate structure which comprises the gate sidewall spacers 130 and 132 as discussed above, and the metal gate 140 comprising a split metal gate structure. The metal gate 340 shown in FIG. 3 is similar to the metal gate 140 of the stacked complementary transistor structure 108 discussed above, in that the metal gate 340 comprises, e.g., (i) the high-k dielectric layers 142 formed on the channel layers 111, 112, 121, 122, and 123 of the first and second transistors 110 and 120, (ii) the first work function metal layer 144 which encapsulates the channel layers 111 and 112 of the first transistor 110, and (iii) the second work function metal layer 146 which encapsulates the channel layers 121, 122, and 123 of the second transistor 120. However, the metal gate 340 comprises a split gate structure which comprises a first metal gate electrode 341, a second metal gate electrode 342, a first insulating layer 350 (or first isolation layer), a second insulating layer 360 (or second isolation layer), and a deep via 370 disposed in the second insulating layer 360 and in contact with the first metal gate electrode 341.

As schematically illustrated in FIG. 3, the first metal gate electrode 341 is disposed around and in contact with the first work function metal layer 144 of the first transistor 110, essentially forming a first metal gate 340-1 for the first transistor 110. In addition, the second metal gate electrode 342 is disposed around and in contact with the second work function metal layer 146 of the second transistor 120, essentially forming a second metal gate 340-2 for the second transistor 120. The first insulating layer 350 and the second insulating layer 360 are configured to electrically isolate the first metal gate 340-1 and the second metal gate 340-2 from each other.

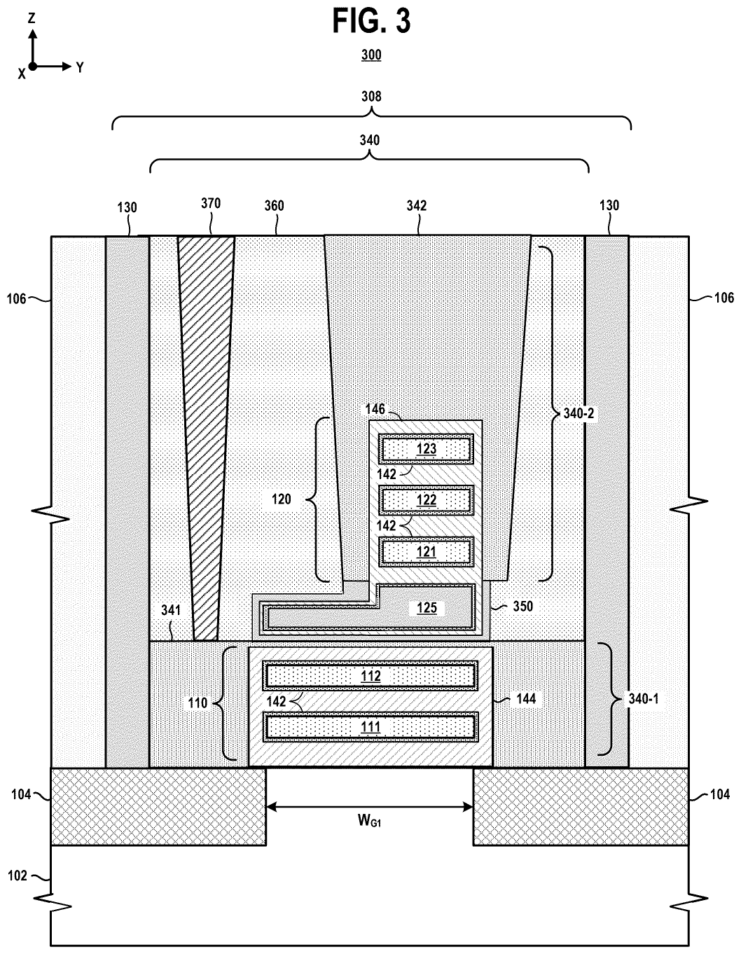

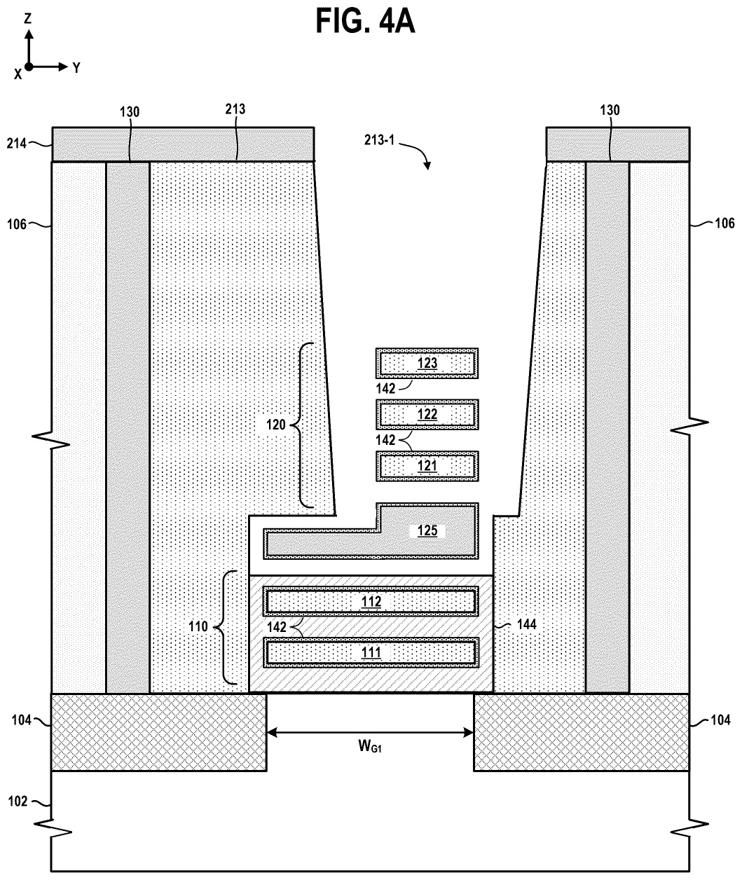

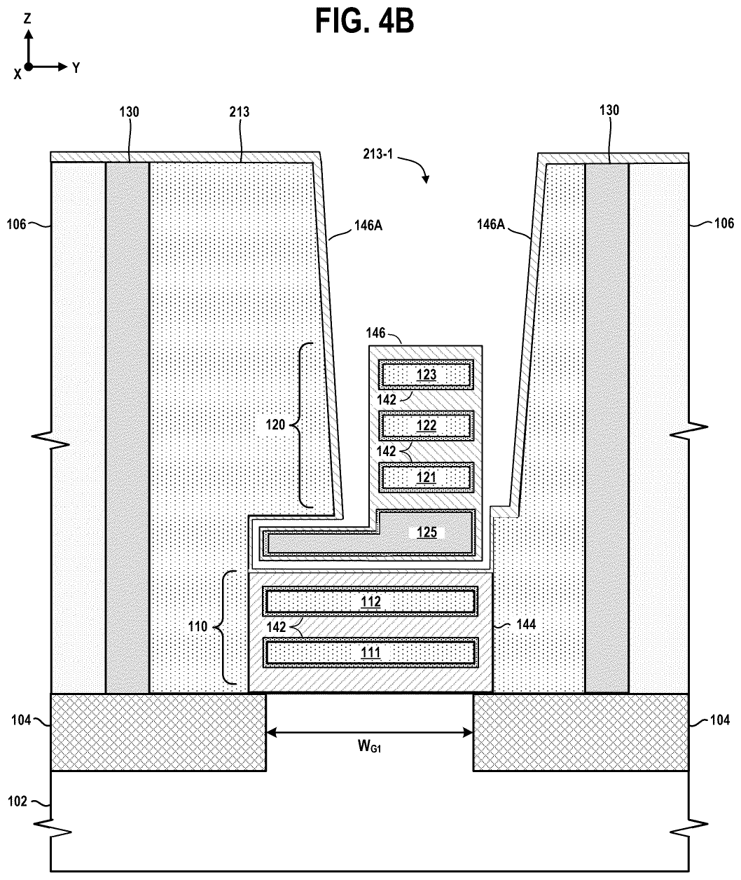

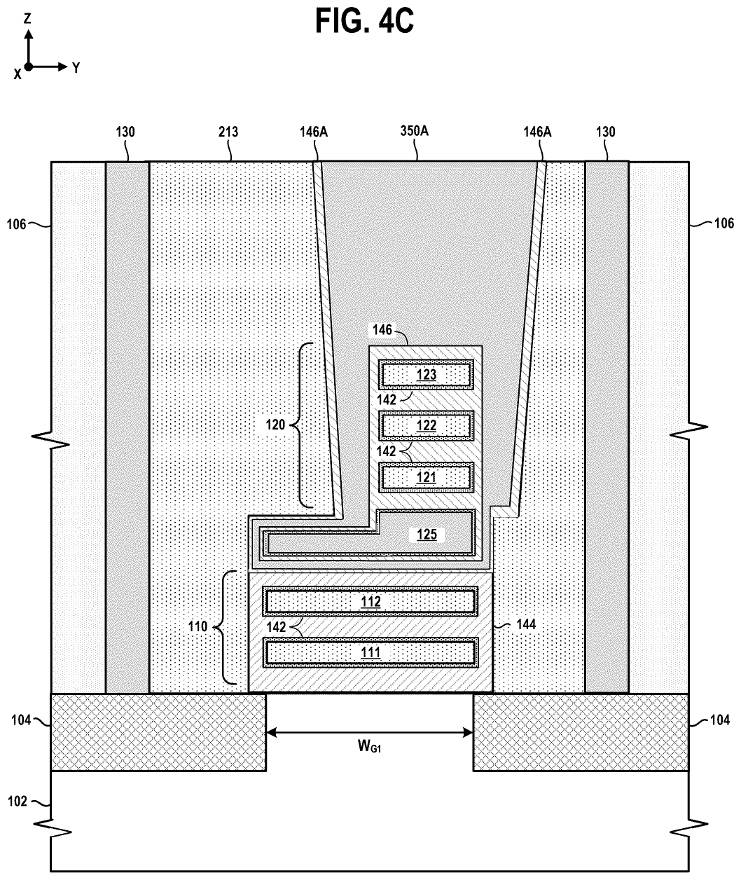

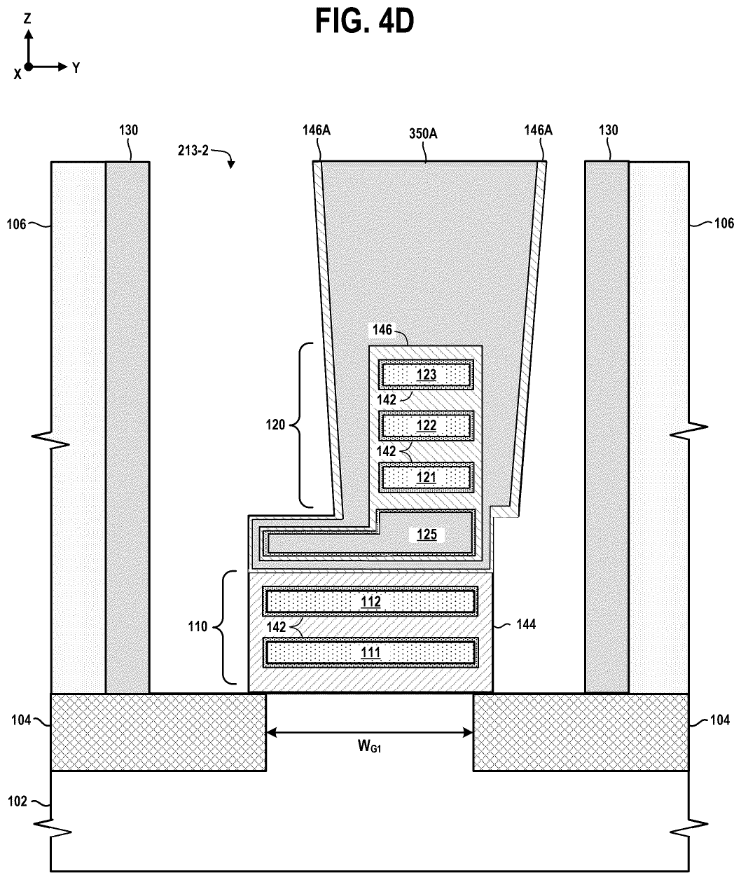

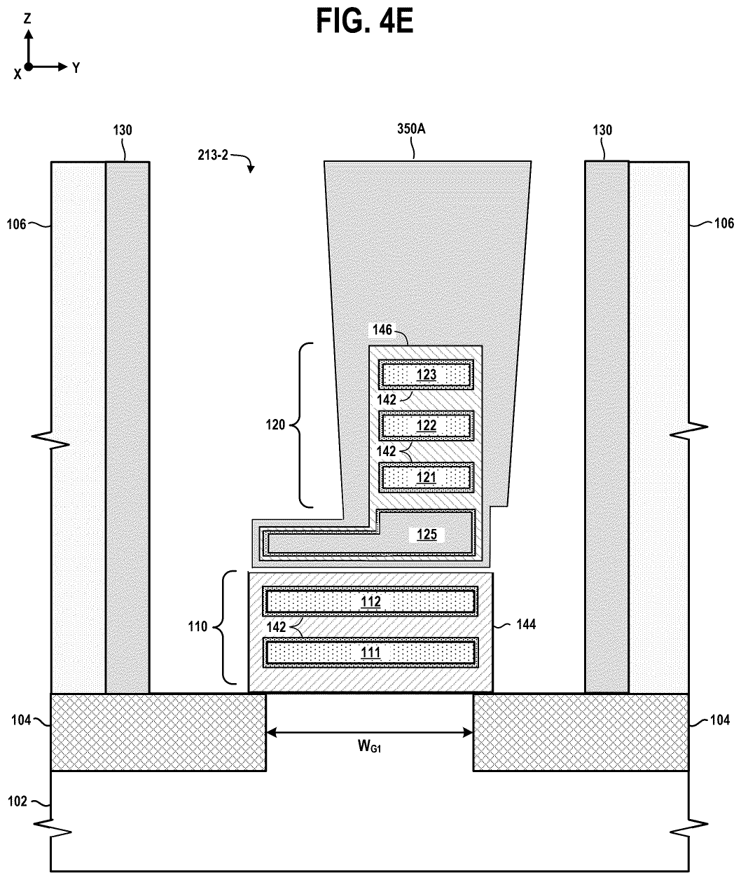

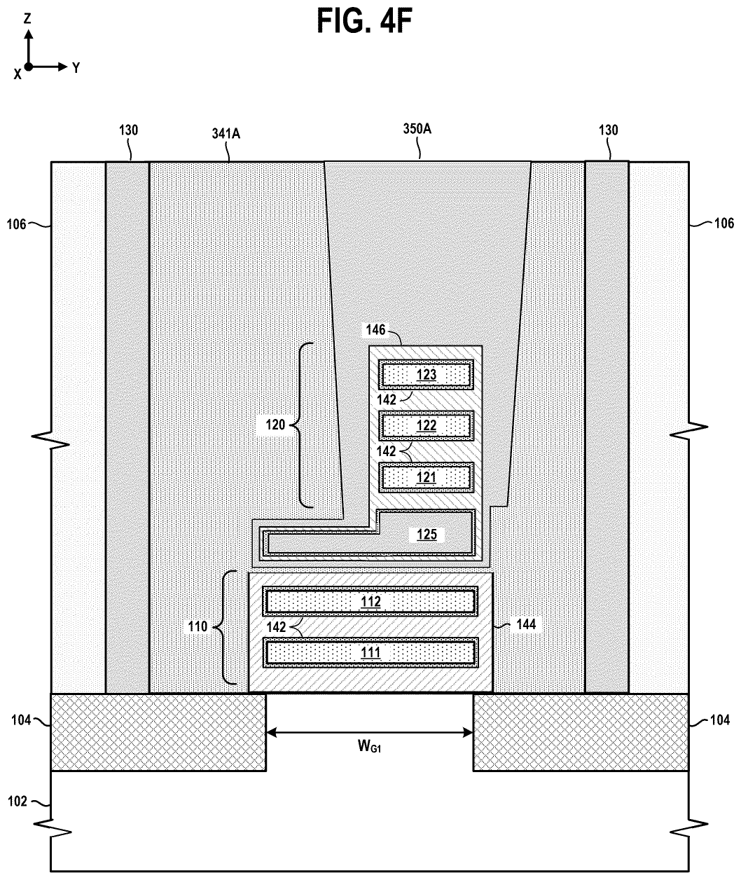

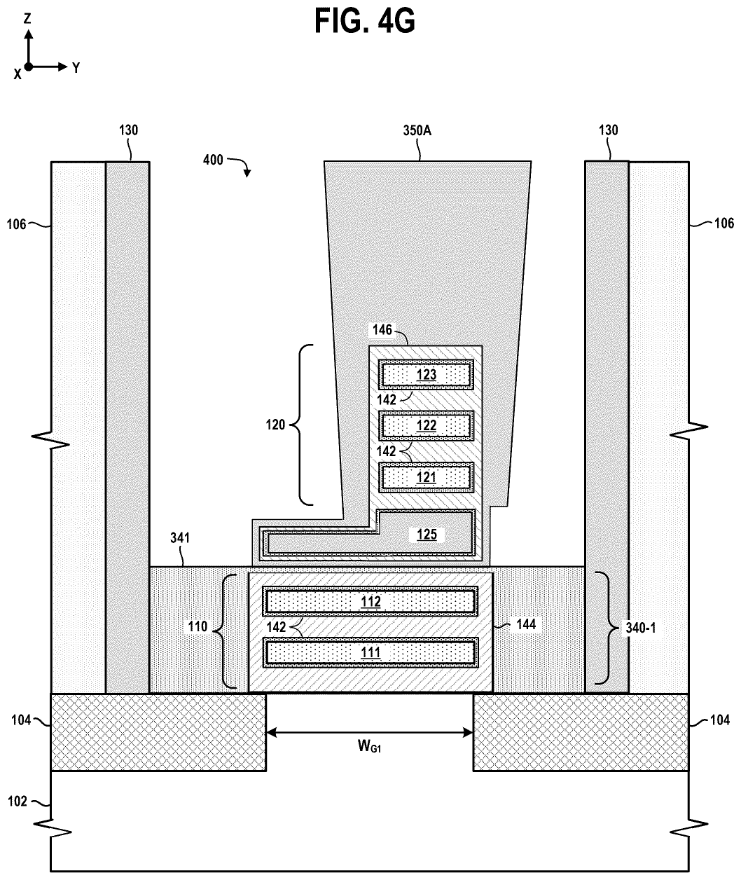

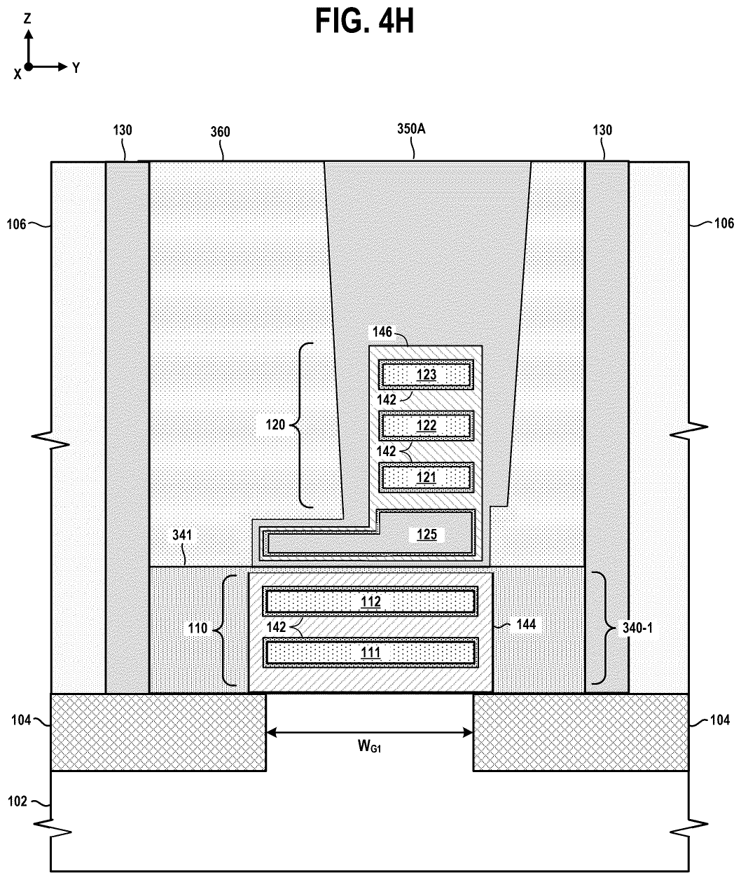

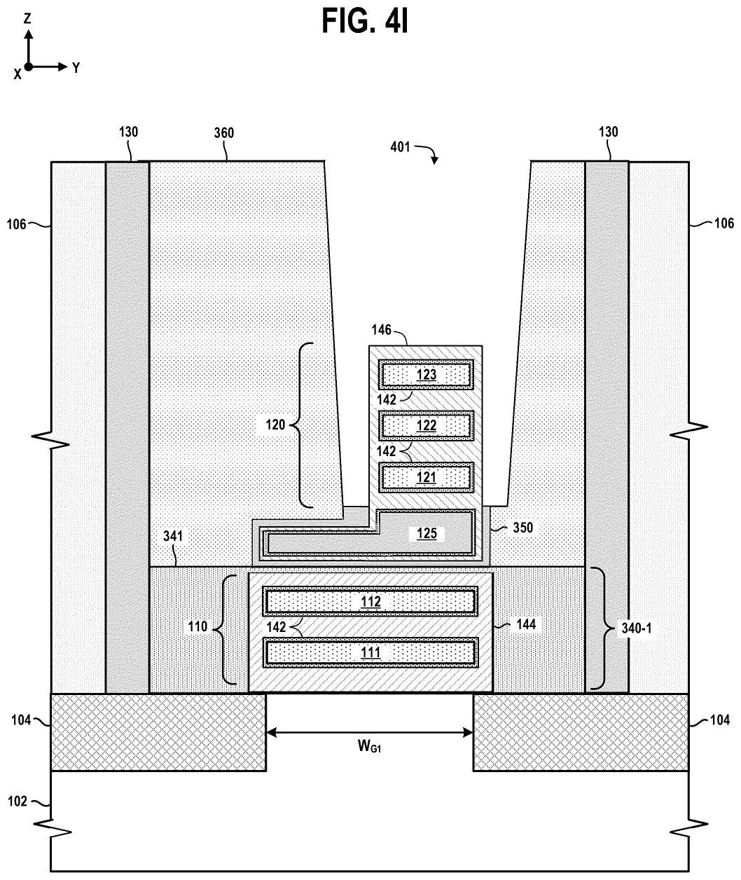

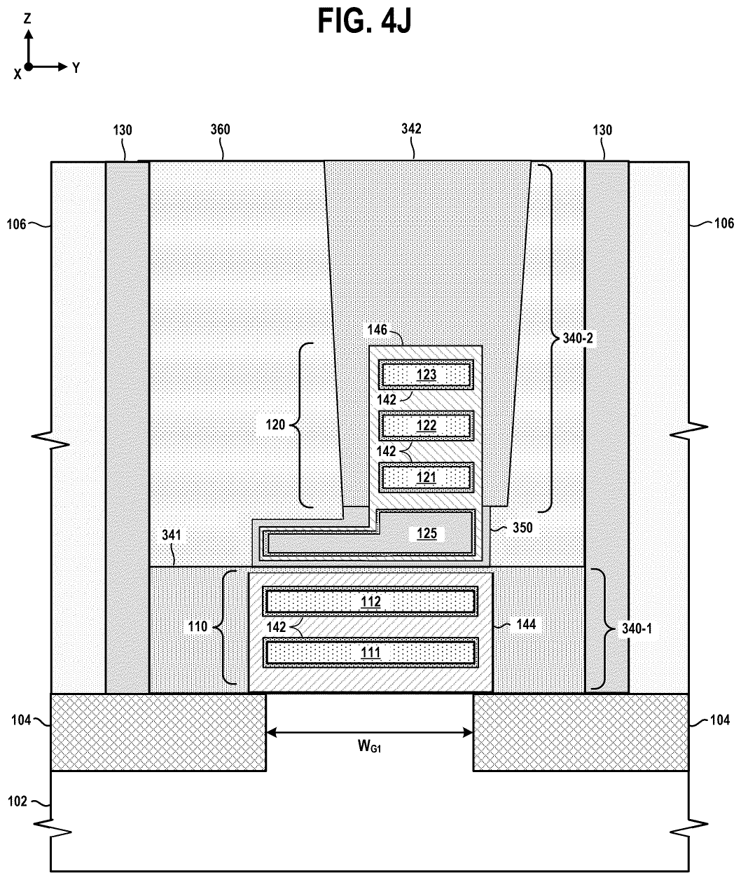

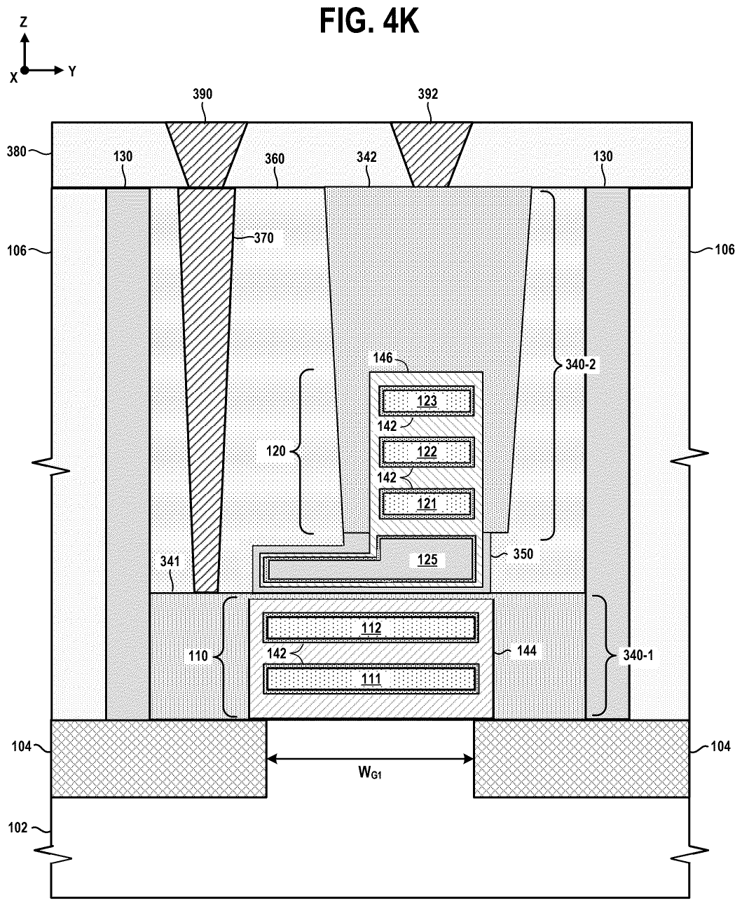

FIGS. 4A-4K schematically illustrate a method for fabricating a semiconductor integrated circuit device comprising a stacked complementary transistor structure, according to another embodiment of the disclosure. In particular, FIGS. 4A-4K schematically illustrate a method for fabricating the semiconductor integrated circuit device 300 of FIG. 3. In some embodiments, FIGS. 4A-4K schematically illustrate an exemplary process flow of exemplary replacement metal gate (RMG) process to form the split gate structure of the metal gate 340, which is performed subsequent to the exemplary processing steps described above in conjunction FIGS. 2A-2G, the details of which need not be repeated. In this regard, the process flow of FIGS. 4A-4K begins starting with the exemplary intermediate structure shown in FIG. 2G in which the trench opening 213-1 is formed in the layer of sacrificial material 213 to expose a portion of the first work function metal layer 144 which encapsulates the channel layers 121, 122, and 123 of the second transistor 120.

FIG. 4A is a schematic cross-sectional side view of an intermediate structure of the semiconductor integrated circuit device 300 which is obtained after removing the portion of the first work function metal layer 144 which is exposed by the trench opening 213-1. In FIG. 4A, the exposed portion of the first work function metal layer 144 is etched selective to the materials of the layer of sacrificial material 213 and the high-k dielectric layers 142 to selectively remove the portion of the first work function metal layer 144 surrounding the channel layers 121, 122, and 123 of the second transistor 120, and down to a level below the MDI layer 125 (e.g., remove the portion of the first work function metal layer 144 surrounding the MDI layer 125). This is to be contrasted with the intermediate structure shown in FIG. 2H, where the first work function metal layer 144 is recessed down to the upper level of the MDI layer 125 to thereby remove the portion of the first work function metal layer 144 surrounding the channel layers 121, 122, and 123 of the second transistor 120, while leaving a portion of the first work function metal layer 144 surrounding the side and bottom surfaces of the MDI layer 125. As noted above, the first work function metal layer 144 can be selectively removed using any suitable isotropic etch process with an etch chemistry that is configured to etch the first work function metal layer 144 highly selective to the materials of the layer of sacrificial material 213 and the high-k dielectric layers 142.

Next, FIG. 4B is a schematic cross-sectional side view of an intermediate structure of the semiconductor integrated circuit device 300 which is obtained after conformally depositing one or more layers of work function metal to form the second work function metal layer 146 which encapsulates the channel layers 121, 122, and 123 of the second transistor 120. As noted above, in some embodiments, the second work function metal layer 146 is formed of TiN, with a thickness of about 2 nm, or other types of work functions metals that are suitable to obtain desired electrical characteristics of the metal gate for the second transistor 120 (e.g., P-type MOSFET). As schematically shown in FIG. 4B, the conformal deposition of the one or more layers of work function metal results in the formation of a thin residual layer 146A of the second work function metal layer 146 on the sidewalls of the trench opening 213-1 of the layer of sacrificial material 213, as well as thin residual conformal layers of work function metal on exposed surfaces adjacent to the sides and bottom regions of the MDI layer 125.

Next, FIG. 4C is a schematic cross-sectional side view of an intermediate structure of the semiconductor integrated circuit device 300 which is obtained after filling the trench opening 213-1 (in the layer of sacrificial material 213) with a first layer of dielectric material 350A. As schematically shown in FIG. 4C, the first layer of dielectric material 350A fills the empty spaces adjacent to the side and bottom surfaces of the MDI layer 125. The first layer of dielectric material 350A is recessed in a later stage of the fabrication process to form the first insulating layer 350 shown in FIG. 3. In some embodiments, the first layer of dielectric material 350A comprises any suitable dielectric material that is suitable for the given application including, but not limited to, SiO₂, SiOC, SiCN, etc. The first layer of dielectric material 350A is deposited using a suitable deposition process which is capable of filling the small empty spaces adjacent to the side and bottom surfaces of the MDI layer 125. For example, in some embodiments, the first layer of dielectric material 350A is formed using a liquid flowable CVD (FCVD) process which is capable of filling high aspect ratio trenches and filling the small empty spaces adjacent to the side and bottom surfaces of the MDI layer 125.

Next, FIG. 4D is a schematic cross-sectional side view of an intermediate structure of the semiconductor integrated circuit device 300 which is obtained after removing a remaining portion of the layer of sacrificial material 213 to form an open gate region 213-2 and thereby expose the first work function metal layer 144 of the first transistor 110 and the thin residual layer 146A of the second work function metal layer 146 on the surfaces of the first layer of dielectric material 350A. As noted above, in some embodiments, a wet etch process is performed using hot ammonium hydroxide (NH₄OH) to remove the remaining portion of the layer of sacrificial material 213 selective to the first work function metal layer 144 and the materials of other surrounding elements (e.g., elements 106, 130, 146A, 148-2, etc.). For example, in some embodiments, the remaining portion of the layer of sacrificial material 213 is removed using a wet etch process comprising hot ammonium hydroxide (NH₄OH).

Next, FIG. 4E is a schematic cross-sectional side view of an intermediate structure of the semiconductor integrated circuit device 300 which is obtained after removing the thin residual layer 146A of the second work function metal layer 146 on the surfaces of the first layer of dielectric material 350A. The thin residual layer 146A of the second work function metal is removed by performing an etch process with an etch chemistry that is configured to etch the thin residual layer 146A of the second work function metal highly selective to the first work function metal layer 144.

Next, FIG. 4F is a schematic cross-sectional side view of an intermediate structure of the semiconductor integrated circuit device 300 which is obtained after filling the open gate region 213-2 with a layer of low-resistance metallic material 341A such as tungsten or other types of low-resistance metallic materials as noted above. The layer of low-resistance metallic material 341A is formed by depositing a low-resistance metallic material to fill the open gate region 213-2, followed by a CMP process to remove the overburden metallic material and planarize the surface of the semiconductor structure down to the pre-metallization dielectric layer 106.

Next, FIG. 4G is a schematic cross-sectional side view of an intermediate structure of the semiconductor integrated circuit device 300 which is obtained after recessing the layer of low-resistance metallic material 341A down to a level below the MDI layer 125 to form the first metal gate electrode 341 and an open region 400 above the first metal gate electrode 341. As noted above, the first metal gate electrode 341 is disposed around and in contact with the first work function metal layer 144 of the first transistor 110, essentially forming the first metal gate 340-1 for the first transistor 110. The layer of low-resistance metallic material 341A is recessed using a suitable etch process with an etch chemistry that is configured to etch the layer of low-resistance metallic material 341A selective to the materials of the surrounding features (e.g., gate sidewall spacer 130 and the first layer of dielectric material 350A, etc.). The etching process is terminated using a timed etch process, resulting in the formation of the first metal gate electrode 341 in contact with the first work function metal layer 144.

Next, FIG. 4H is a schematic cross-sectional side view of an intermediate structure of the semiconductor integrated circuit device 300 which is obtained after filling the open region 400 above the first metal gate electrode 341 with dielectric material to form the second insulating layer 360. In some embodiments, the second insulating layer 360 is formed of a dielectric material, which has etch selectivity with respect to the material of the first layer of dielectric material 350A. For example, in some embodiments, the second insulating layer 360 is formed of SiN. The second insulating layer 360 is formed by depositing a layer of dielectric material to fill the open region 400, followed by a CMP process to remove the overburden material and planarize the surface of the intermediate device structure down to the pre-metallization dielectric layer 106.

Next, FIG. 41 is a schematic cross-sectional side view of an intermediate structure of the semiconductor integrated circuit device 300 which is obtained after recessing the first layer of dielectric material 350A down to a level of the MDI layer 125 to form an open cavity 401 which exposes the second work function metal layer 146 and results in the formation of the first insulating layer 350. The first layer of dielectric material 350A is recessed using an etch process with an etch chemistry that is configured to etch the dielectric material (e.g., SiO₂) of the first layer of dielectric material 350A selective to the material (e.g., SiN) of the second insulating layer 360, and utilizing a timed etch to terminate the etching of the first layer of dielectric material 350A at the level of the MDI layer 125.

Next, FIG. 4J is a schematic cross-sectional side view of an intermediate structure of the semiconductor integrated circuit device 300 which is obtained after filling the open cavity 401 with a layer of low-resistance metallic material to form the second metal gate electrode 342, which is disposed around and in contact with the second work function metal layer 146 of the second transistor 120, thereby forming the second metal gate 340-2 for the second transistor 120. The second metal gate electrode 342 is formed by depositing a layer of low-resistance metallic material (such as tungsten) to fill the open cavity 401, followed by CMP process to remove the overburden metallic material and planarize the surface of the semiconductor structure down to the pre-metallization dielectric layer 106.

Next, FIG. 4K is a schematic cross-sectional side view of an intermediate structure of the semiconductor integrated circuit device 300 which is obtained after forming the deep via 370 (or gate via contact) in the second insulating layer 360 to provide a gate contact to the underlying first metal gate electrode 341 of the first transistor 110, resulting in the intermediate structure of the semiconductor integrated circuit device 300 shown in FIG. 3. In some embodiments, the deep via 370 is formed as part of middle-of-the-line (MOL) process module in which via contacts are also formed in the pre-metallization dielectric layer 106 to provide source/drain contacts to the source/drain elements of the first and second transistors 110 and 120. The deep via 370 is formed by a process which comprises forming a via hole in the second insulating layer 360 down the first metal gate electrode 341, and filling the via hole with a metallic material such as tungsten or cobalt, etc., to form the deep via 370. In some embodiments, a thin diffusion barrier layer is first deposited to line the inner surface of the via hole, followed by the deposition of the via metal.

FIG. 4K further shows a next intermediate structure of the semiconductor integrated circuit device 300 after forming a MOL layer on the pre-metallization dielectric layer 106. The MOL layer comprises an interlevel dielectric (ILD) layer 380, and additional contacts 390 and 392 (or plugs). As schematically illustrated in FIG. 4K, the contact 390 is in contact with the deep via 370, and thus provides a contact to the first metal gate electrode 341. The contact 292 is in direct contact with the second metal gate electrode 342. The additional contacts 390 and 392 facilitate local connections to the first metal gate 340-1 and the second metal gate 340-2 of the first and second transistors 110 and 120.

It is to be understood that the techniques disclosed herein can be implemented to form both stacked complementary transistor structures with common metal gate structures, and stacked complementary transistor structures with split gate structures, on common substrate. In addition, the techniques disclosed herein can be implemented in conjunction with stacked complementary transistor structures in which the first and second transistor have separate gate structures to enable independent gate control of the first and second transistors.

It is to be understood that the exemplary methods discussed herein for fabricating stacked complementary transistor structures can be readily incorporated within semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit as disclosed herein can be employed in applications, hardware, and/or electronic systems. Suitable hardware and systems for implementing the exemplary embodiments described herein may include, but are not limited to, personal computers, communication networks, electronic commerce systems, portable communications devices (e.g., cell and smart phones), solid-state media storage devices, functional circuitry, etc. Systems and hardware incorporating such integrated circuits are considered part of the exemplary embodiments described herein. Given the teachings of the disclosure provided herein, one of ordinary skill in the art will be able to contemplate other implementations and applications of the exemplary techniques disclosed herein.

Moreover, the exemplary structures described above may be implemented in integrated circuits chips. The resulting integrated circuit chips can be distributed by a fabricator in raw wafer form (that is, as a single wafer that has multiple unpackaged chips), as a bare die, or in a packaged form. In the latter case, a chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a stacked transistor structure which comprises a first transistor of a first type, and a second transistor of a second type which is opposite the first type, and disposed over the first transistor; and
a shared gate structure which comprises a first metal gate structure of the first transistor, and a second metal gate structure of the second transistor, wherein the second metal gate structure is embedded in the first metal gate structure.

2. The device of claim 1, wherein:
the first metal gate structure comprises a first work function metal layer encapsulating at least one channel layer of the first transistor;
the second metal gate structure comprises a second work function metal layer encapsulating at least one channel layer of the second transistor; and
a first portion of the first work function metal layer is disposed in contact with a second portion of the second work function metal layer.

3. The device of claim 2, further comprising:
a dielectric isolation layer disposed between the at least one channel layer of the first transistor and the at least one channel layer of the second transistor;
wherein a first portion of the dielectric isolation layer is covered by the first portion of the first work function metal layer; and
wherein a second portion of the dielectric isolation layer is covered by the second portion of the second work function metal layer.

4. The device of claim 1, wherein:
the first metal gate structure comprises a first work function metal layer encapsulating at least one channel layer of the first transistor, and a first gate electrode in contact with the first work function metal layer;
the second metal gate structure comprises a second work function metal layer encapsulating at least one channel layer of the second transistor, and a second gate electrode in contact with the second work function metal layer; and
the first gate electrode and the second gate electrode are electrically coupled by a portion of the second work function metal layer disposed between and in contact with the first gate electrode and the second gate electrode.

5. The device of claim 1, wherein:
the first transistor and the second transistor each comprise one or more channel layers;
the one or more channel layers are encapsulated by respective dielectric layers; and
the dielectric layers are nominally identical in composition and thickness.

6. The device of claim 5, wherein:
the one or more channel layers comprise respective interfacial layers formed on surfaces thereof; and
the interfacial layers are nominally identical in composition and thickness.

7. The device of claim 1, wherein:
the first transistor and the second transistor each comprise a gate-all-around nanosheet field-effect transistor; and
the first transistor is a P-type transistor and the second transistor is an N-type transistor, or the first transistor is an N-type transistor and the second transistor is a P-type transistor.

8. A device, comprising:
a stacked transistor structure which comprises a first transistor of a first type, and a second transistor of a second type which is opposite the first type, and disposed over the first transistor; and
a split gate structure which comprises a first dielectric isolation layer, a first metal gate structure of the first transistor, and a second metal gate structure of the second transistor which are isolated at least in part by the first dielectric isolation layer;
wherein the second metal gate structure is embedded in the first dielectric isolation layer; and
wherein the first metal gate structure is disposed below the first dielectric isolation layer.

9. The device of claim 8, wherein:
the first metal gate structure comprises a first work function metal layer encapsulating at least one channel layer of the first transistor;
the second metal gate structure comprises a second work function metal layer encapsulating at least one channel layer of the second transistor; and
the split gate structure further comprises a second dielectric isolation layer which electrically isolates the first work function metal layer and the second work function metal layer from each other.

10. The device of claim 9, further comprising:
a third dielectric isolation layer disposed between the at least one channel layer of the first transistor and the at least one channel layer of the second transistor;
wherein the third dielectric isolation layer is encapsulated by a portion of the second work function metal layer; and
wherein the second dielectric isolation layer encapsulates the portion of the second work function metal layer that encapsulates the third dielectric isolation layer.

11. The device of claim 8, further comprising a via contact disposed in the first dielectric isolation layer and in contact with the first metal gate structure disposed below the first dielectric isolation layer.

12. The device of claim 8, wherein:
the first transistor and the second transistor each comprise one or more channel layers;
the one or more channel layers are encapsulated by respective dielectric layers; and
the dielectric layers are nominally identical in composition and thickness.

13. The device of claim 12, wherein:
the one or more channel layers comprise respective interfacial layers formed on surfaces thereof; and
the interfacial layers are nominally identical in composition and thickness.

14. The device of claim 8, wherein:
the first transistor and the second transistor each comprise a gate-all-around nanosheet field-effect transistor; and
the first transistor is a P-type transistor and the second transistor is an N-type transistor, or the first transistor is an N-type transistor and the second transistor is a P-type transistor.

15. A device, comprising:
a substrate;
a first stacked transistor structure and a second stacked transistor structure disposed on the substrate;
wherein the first stacked transistor structure comprises:
a first transistor of a first type, and a second transistor of a second type which is opposite the first type, and disposed over the first transistor; and
a shared metal gate structure which comprises a first metal gate structure of the first transistor, and a second metal gate structure of the second transistor, wherein the second metal gate structure is embedded in the first metal gate structure; and
wherein the second stacked transistor structure comprises:
a third transistor of a first type, and a fourth transistor of a second type which is opposite the first type, and disposed over the third transistor; and
a split gate structure which comprises a first dielectric isolation layer, a first metal gate structure of the third transistor, and a second metal gate structure of the fourth transistor which are isolated at least in part by the first dielectric isolation layer;
wherein the second metal gate structure of the fourth transistor is embedded in the first dielectric isolation layer; and
wherein the first metal gate structure of the third transistor is disposed below the first dielectric isolation layer.

16. A method, comprising:
forming a stacked transistor structure which comprises a first transistor of a first type, a second transistor of a second type, which is opposite the first type and disposed over the first transistor; and
forming a shared gate structure which comprises a first metal gate structure of the first transistor, and a second metal gate structure of the second transistor, wherein the second metal gate structure is embedded in the first metal gate structure.

17. The method of claim 16, wherein:
the first metal gate structure comprises a first work function metal layer which encapsulates first channel layers of the first transistor, and a first gate electrode in contact with the first work function metal layer; and
the second metal gate structure comprises a second work function metal layer which encapsulates second channel layers of the second transistor, and a second gate electrode in contact with the second work function metal layer.

18. The method of claim 17, wherein:
forming the stacked transistor structure comprises forming an initial stacked transistor structure in which the first channel layers and the second channel layers are encapsulated by the first work function metal layer; and
forming the shared gate structure comprises:
forming a sacrificial material layer over the initial stacked transistor structure;
forming a trench opening in the sacrificial material layer to expose a portion of the first work function metal layer encapsulating the second channel layers of the second transistor;
removing the exposed portion of the first work function metal layer;
depositing a layer of work function metal to form the second work function metal layer which encapsulates the second channel layers of the second transistor and to form a liner layer of work function metal on sidewalls of the trench opening;
filling the trench with metallic material to form the second gate electrode in contact with the liner layer of work function metal;
removing a remaining portion of the sacrificial material layer to form an open region which exposes a remaining portion of the first work function metal layer encapsulating the first channel layers of the first transistor; and
filling the open region with metallic material to form the first gate electrode in contact with the remaining portion of the first work function metal layer and the liner layer of work function metal.

19. The method of claim 18, wherein forming the trench opening in the sacrificial material layer comprises etching the trench opening down to a level of a dielectric isolation layer of the stacked transistor structure which is disposed between the first channel layers and the second channel layers.

20. The method of claim 18, wherein forming the initial stacked transistor structure comprises:
forming an interfacial layer and dielectric layer on each of the first channel layers and the second channel layers; and
forming the first work function metal layer to encapsulate the first channel layers and the second channel layers with the interfacial layers and dielectric layers;
wherein the interfacial layers are nominally identical in composition and thickness; and
wherein the dielectric layers are nominally identical in composition and thickness.

21. A method, comprising:
forming a stacked transistor structure which comprises a first transistor of a first type, and a second transistor of a second type which is opposite the first type, and disposed over the first transistor; and
forming a split gate structure which comprises a first dielectric isolation layer, a first metal gate structure of the first transistor, and a second metal gate structure of the second transistor which are isolated at least in part by the first dielectric isolation layer, wherein the second metal gate structure is embedded in the first dielectric isolation layer, the first metal gate structure is disposed below the first dielectric isolation layer.

22. The method of claim 21, wherein:
the first metal gate structure comprises a first work function metal layer which encapsulates first channel layers of the first transistor, and a first gate electrode in contact with the first work function metal layer; and
the second metal gate structure comprises a second work function metal layer which encapsulates second channel layers of the second transistor, and a second gate electrode in contact with the second work function metal layer.

23. The method of claim 22, wherein:
forming the stacked transistor structure comprises forming an initial stacked transistor structure in which the first channel layers and the second channel layers are encapsulated by the first work function metal layer; and
forming the split gate structure comprises:
forming a sacrificial material layer over the initial stacked transistor structure;
forming a first trench opening in the sacrificial material layer to expose a portion of the first work function metal layer encapsulating the second channel layers of the second transistor;
removing the exposed portion of the first work function metal layer;
depositing a work function metal to form the second work function metal layer which encapsulates the second channel layers of the second transistor and to form a liner layer of work function metal on sidewalls of the first trench opening;
filling the first trench opening with a first layer of dielectric material;
removing a remaining portion of the sacrificial material layer and the liner layer of work function metal to form an open region which exposes a remaining portion of the first work function metal layer encapsulating the first channel layers of the first transistor;
forming the first gate electrode in a bottom portion of the open region in contact with the remaining portion of the first work function metal layer;
filling a remaining portion of the open region with a second layer of dielectric material;
removing the first layer of dielectric material selective to the second layer of dielectric material to form a second trench opening in the second layer of dielectric material to exposes a portion of the second work function metal layer; and
forming the second gate electrode in the second trench opening in contact with the exposed portion of the second work function metal layer.

24. The method of claim 23, wherein:
forming the first trench opening in the sacrificial material layer comprises etching the first trench opening in the sacrificial material layer down to a level below a middle dielectric isolation layer of the stacked transistor structure which is disposed between the first channel layers and the second channel layers; and
filling the first trench opening with the first layer of dielectric material comprises filling the first trench opening to encapsulate the middle dielectric isolation layer within the first layer of dielectric material.

25. The method of claim 23, wherein forming the initial stacked transistor structure comprises:
forming an interfacial layer and dielectric layer on each of the first channel layers and the second channel layers; and
forming the first work function metal layer to encapsulate the first channel layers and the second channel layers with the interfacial layers and dielectric layers;
wherein the interfacial layers are nominally identical in composition and thickness; and
wherein the dielectric layers are nominally identical in composition and thickness.
